(19) United States
(12) Patent Application Publication
(10) Pub. No.: US 2025/0273170 A1
(43) Pub. Date: Aug. 28, 2025

(54) DISPLAY PANEL AND DISPLAY DEVICE INCLUDING THE SAME

(71) Applicant: LG Display Co., Ltd., Seoul (KR)

(72) Inventors: Jin Seong KIM, Paju-si (KR); Ju Han KIM, Paju-si (KR)

(73) Assignee: LG Display Co., Ltd., Seoul (KR)

(21) Appl. No.: 18/969,985

(22) Filed: Dec. 5, 2024

(30) Foreign Application Priority Data
Feb. 28, 2024 (KR) 10-2024-0029206

(51) Int. Cl. G09G 3/3275; G09G 3/32; G09G 3/3266

(52) U.S. Cl. CPC G09G 3/3275; G09G 3/32; G09G 3/3266; G09G 2300/0426; G09G 2310/0267; G09G 2310/0275; G09G 2330/021

(57) ABSTRACT

A display panel may include a substrate; a driving element disposed on the substrate; a first switch element disposed on the substrate; a driving voltage wire electrically connected to the first switch element; and a compensation electrode layer electrically connected to the driving voltage wire, wherein the driving voltage wire and the compensation electrode layer are disposed on different layers, and a display device including the same.

### CROSS-REFERENCE TO RELATED APPLICATION

This application claims priority to and the benefit of Korean Patent Application No. 10-2024-0029206, filed Feb. 28, 2024, the disclosure of which is incorporated herein by reference in its entirety.

### FIELD

Embodiments of the present disclosure relate to a display panel and a display device including the same.

### DESCRIPTION OF RELATED ART

An electroluminescent display may be categorized, for example, into inorganic light-emitting display devices and organic light-emitting display devices, according to the material of an emissive layer. An active matrix type organic light-emitting display device includes an organic light-emitting diode (hereinafter referred to as “OLED”) that emits light by itself and has the advantages of fast response speed and large light-emitting efficiency, luminance, and viewing angle. In the organic light-emitting display device, the OLED is formed in each pixel. The organic light-emitting display device has a fast response speed and excellent light-emitting efficiency, luminance, and viewing angle, as well as an excellent contrast ratio and color reproducibility, as it may express black grayscales in full black.

However, when driving the display panel, the pulse width modulation (PWM) signal is applied to a switch transistor, causing ripple in the driving voltage, and the ripple in the driving voltage is applied to the node of a driving transistor, causing poor image quality.

### SUMMARY

The present disclosure is directed to a display panel and a display device including the same that substantially obviate one or more of the problems due to limitations and disadvantages of the related art.

Embodiments of the present disclosure provide a display panel including a compensation electrode layer connected to a driving voltage wire for reducing fluctuations in a driving voltage EVDD (also referred to as a pixel driving voltage EVDD) due to a pulse driving, and a display device including the same.

The objects of the present disclosure and the problems to be solved are not limited to those mentioned above, and other objects and problems to solve not mentioned can be clearly understood by those skilled in the art from the following description.

To achieve these objects and other advantages of the present disclosure, as embodied and broadly described herein, a display panel according to an embodiment of the present disclosure includes a substrate; a driving element disposed on the substrate; a first switch element disposed on the substrate; a driving voltage wire electrically connected to the first switch element; and a compensation electrode layer electrically connected to the driving voltage wire, wherein the driving voltage wire and the compensation electrode layer are disposed on different layers.

According to some embodiments, an image with improved quality may be implemented by reducing the resistance of the driving voltage wire to suppress luminance changes.

According to some embodiments, the formation of parasitic capacitors may be suppressed by positioning the compensation electrode layer to correspond to the driving voltage wire and the metal pattern.

According to some embodiments, the compensation electrode layer may be extended to the non-display area to suppress moisture penetration, thereby improving the reliability of the display panel.

The effects of the present disclosure are not limited to the above-mentioned effects, and other effects that are not mentioned can be apparently understood by those skilled in the art from the following description and the appended claims.

### BRIEF DESCRIPTION OF THE DRAWINGS

The accompanying drawings, which are included to provide a further understanding of the disclosure and are incorporated in and constitute a part of this application, illustrate example embodiments of the disclosure and together with the description serve to explain the principles of the disclosure. In the drawings:

FIG. 1 is a block diagram illustrating a display device according to an example embodiment of the present disclosure;

FIG. 2 is a cross-sectional view illustrating an example cross-sectional structure of the display device shown in FIG. 1;

FIG. 3 is a diagram illustrating example stabilization capacitors connected to sub-pixels;

FIG. 4 is a circuit diagram illustrating a pixel circuit according to an example embodiment of the present disclosure;

FIG. 5 is a waveform diagram illustrating gate signals applied to the pixel circuit shown in FIG. 4 and voltages of main nodes;

FIG. 6 is a circuit diagram illustrating a pixel circuit according to another example embodiment of the present disclosure;

FIG. 7 is a cross-sectional view of a sub-pixel in an example display panel according to a first embodiment of the present disclosure;

FIG. 8 shows (a) a plan view and (b) a cross-sectional view of an example display panel in which up to an electrode pattern and a driving voltage wire are stacked according to a first embodiment of the present disclosure;

FIG. 9 shows (a) a plan view and (b) a cross-sectional view of an example display panel in which up to a second planarization layer is stacked according to a first embodiment of the present disclosure;

FIG. 10 shows (a) a plan view and (b) a cross-sectional view of an example display panel in which up to a compensation electrode layer is stacked according to a first embodiment;

FIG. 11 is a plan view of a display panel and a compensation electrode layer according to a first embodiment of the present disclosure;

FIG. 12 is a plan view illustrating a modified example of the compensation electrode layer;

FIG. 13 shows (a) a plan view and (b) a cross-sectional view of an example display panel in which up to a third planarization layer is stacked according to a first embodiment of the present disclosure;

FIG. 14 shows (a) a plan view and (b) a cross-sectional view of an example display panel in which up to an anode electrode is stacked according to a first embodiment of the present disclosure;

FIG. 15 shows (a) a plan view and (b) a cross-sectional view of an example display panel in which up to a bank layer is stacked according to a first embodiment of the present disclosure;

FIG. 16 is a diagram illustrating an example display device with a touch electrode layer disposed thereon;

FIG. 17 is a cross-sectional view of an example display panel according to a second embodiment of the present disclosure;

FIG. 18 is a modified example of FIG. 17;

FIG. 19 is a cross-sectional view of an example display panel according to a third embodiment of the present specification;

FIG. 20 is a diagram illustrating a display area and a non-display area of a display device according to an example embodiment of the present disclosure;

FIG. 21 is a cross-sectional view in the direction of line I-I′ in FIG. 20;

FIG. 22 is a cross-sectional view in the direction of line II-II′ in FIG. 20;

FIG. 23 is a diagram illustrating an example gate driver of a display panel; and

FIG. 24 is a cross-sectional view in the direction of line III-III′ in FIG. 23.

### DETAILED DESCRIPTION

The advantages and features of the present disclosure, and methods of achieving them will be apparent from the embodiments described in detail below in conjunction with the accompanying drawings. However, the present disclosure is not limited to the following embodiments, which may be implemented in various different forms. Rather, the present embodiments will make the disclosure of the present disclosure complete and allow those skilled in the art to fully understand the scope of the present disclosure. The present disclosure is defined only within the scope of the appended claims.

The shapes, sizes, proportions, angles, numbers and the like shown in the accompanying drawings for the purpose of describing the embodiments of the present disclosure are merely examples, and the present disclosure is not limited thereto. Like reference numerals generally denote like elements throughout the present specification. Further, in describing the present disclosure, detailed descriptions of known related technologies may be omitted so as not to unnecessarily obscure the subject matter of the present disclosure.

The terms such as “comprising,” “including,” “having,” and “consisting of” used herein are generally intended to allow other components to be added unless the terms are used with a more limiting term like “only.” References to the singular shall be construed to include the plural, and vice versa, unless expressly stated otherwise.

In interpreting components, they are construed to include a margin of error, even if it is not explicitly stated.

Where a positional or interconnected relationship between two components is described with such terms as “on top of,” “above,” “below,” “next to,” “connect or couple with,” “crossing,” “intersecting,” etc., one or more other components may be interposed between them unless a more limiting term like “immediately” or “directly” is used.

Where a temporal contextual relationship is described with such a term as “after,” “following,” “next to,” or “before,” it may not be continuous on a time scale unless a more limiting term like “immediately” or “directly” is used.

The first, second, and so on may be used to refer to the components separately from one another, but the functions or structures of these components are not limited to the ordinal number or component name attached to the component.

The following embodiments may be combined or associated with each other in whole or in part, and various types of interlocking and driving are technically possible. The embodiments may be implemented independently of each other or together in an interrelated relationship.

In the display device of the present disclosure, the pixel circuit, and the gate driving circuit may include a plurality of transistors. The transistors may be implemented as an oxide thin film transistor (TFT) including an oxide semiconductor or a low temperature poly silicon TFT (LTPS TFT) including a low temperature poly silicon (LTPS). In the following, the transistors constituting the pixel circuit and the gate drive circuit will be described mainly on the basis of an example implemented in an n-channel oxide TFT, but the present disclosure is not limited thereto.

A transistor is a three-electrode element including a gate, a source, and a drain. The source is an electrode that supplies carriers to the transistor. In the transistor, the carriers start to flow from the source. The drain is an electrode through which the carriers exit from the transistor. In the transistor, the carriers flow from the source to the drain. In the case of an n-channel transistor, since the carriers are electrons, a source voltage is lower than a drain voltage such that the electrons can flow from the source to the drain. In the n-channel transistor, the direction of current is from the drain to the source. In the case of a p-channel transistor, since the carriers are holes, a source voltage is higher than a drain voltage such that the holes can flow from the source to the drain. In the p-channel transistor, the current flows from the source to the drain because the holes flow from the source to the drain. It should be noted that the source and the drain of the transistor are not fixed. For example, the source and the drain may be changed according to an applied voltage. Therefore, the present disclosure is not limited by the source and the drain of the transistor. In the following description, the source and the drain of the transistor will be referred to as a ‘first and second electrodes’ and ‘first and second source-drain electrodes (electrode patterns).

A gate signal may include a pulse that swings between a gate-on voltage and a gate-off voltage. The gate-on voltage is set to a voltage higher than the threshold voltage of the transistor. The gate-off voltage is set to a voltage lower than the threshold voltage of the transistor.

The transistor is turned on in response to the gate-on voltage and is turned off in response to the gate-off voltage. In the case of the n-channel transistor, the gate-on voltage may be a gate high voltage VGH, and the gate-off voltage may be a gate low voltage.

Hereinafter, various embodiments of the present disclosure will be described in detail with reference to the accompanying drawings.

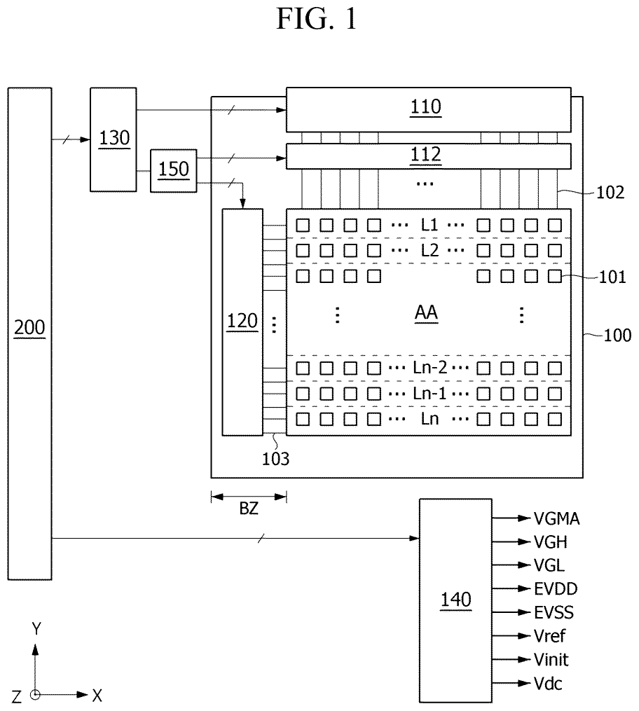

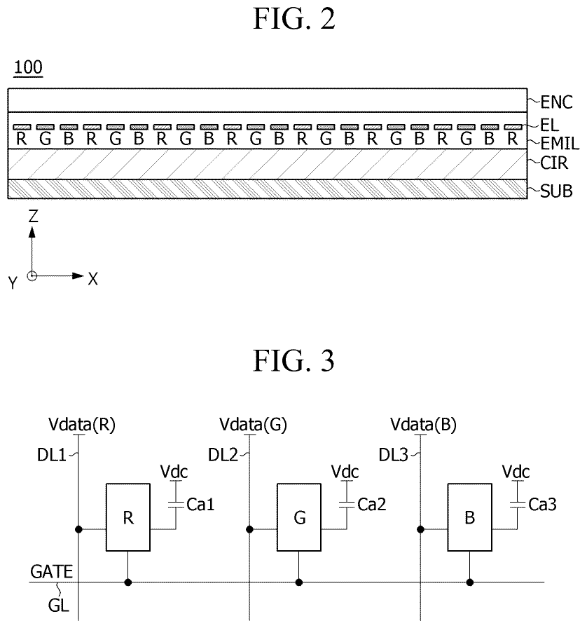

FIG. 1 is a block diagram illustrating a display device according to an example embodiment of the present disclosure. FIG. 2 is a cross-sectional view illustrating an example cross-sectional structure of the display device shown in FIG. 1.

As shown in FIGS. 1 and 2, the display device according to an example embodiment of the present disclosure includes a display panel 100, a display panel driving circuit for writing pixel data to pixels of the display panel 100, and a power supply 140 for generating power for driving the pixels and the display panel driving circuit.

The display panel 100 may be a panel having a rectangular structure with a length in the X-axis direction, a width in the Y-axis direction, and a thickness in the Z-axis direction. A display area AA of the display panel 100 includes a pixel array for displaying an input image thereon. The pixel array includes a plurality of data lines 102, a plurality of gate lines 103 intersected with the data lines 102, and the pixels arranged in a matrix form. The display panel 100 may further include power lines commonly connected to the pixels. The power lines are connected to the constant voltage nodes of the pixel circuits and supply the constant voltage to drive the pixels 101 to the pixels 101.

Each of the pixels 101 may be divided into a red sub-pixel, a green sub-pixel, and a blue sub-pixel for color implementation. Each of the pixels may further include a white sub-pixel. Each of the pixel circuits is connected to a data line, a gate line, and a power line.

The pixels may be arranged in the form of real color pixels and pentile pixels. A pentile pixel may realize a higher resolution than a real color pixel by driving two sub-pixels having different colors as one pixel 101 by using a preset pixel rendering algorithm. The pixel rendering algorithm may compensate for inadequate color representation in each pixel with the color of light emitted from its adjacent pixel.

The pixel array includes a plurality of pixel lines L1 to Ln. Each of the pixel lines L1 to Ln includes one line of pixels arranged along the line direction (X-axis direction) in the pixel array of the display panel 100. The pixels arranged in one pixel line share the gate lines 103. The sub-pixels arranged in the column direction Y along the data line direction share the same data line 102. One horizontal period is a time obtained by dividing one frame period by the total number of the pixel lines L1 to Ln.

The display panel 100 may be implemented as a non-transmissive display panel or a transmissive display panel. The transmissive display panel may be applied to a transparent display device in which an image is displayed on a screen and an actual object in the background is visible. The display panel 100 may be fabricated as a flexible display panel.

The cross-sectional structure of the display panel 100 may include a circuit layer CIR, an emissive element layer EMIL, and an encapsulation layer ENC that are stacked on a substrate SUB, as shown in FIG. 2.

The circuit layer CIR may include a thin-film transistor (TFT) array including a pixel circuit connected to wires such as a data line, a gate line, a power line, and the like, a de-multiplexer array 112, and a gate driver 120. The circuit layer CIR includes a plurality of metal layers insulated with insulating layers interposed therebetween, and a semiconductor material layer. All transistors formed in the circuit layer CIR may be implemented as, but are not limited to, an n-channel oxide TFT.

The emissive element layer EMIL may include a light-emitting element EL driven by the pixel circuit. The light-emitting element EL may include a light-emitting element of a red sub-pixel, a light-emitting element of a green sub-pixel, and a light-emitting element of a blue sub-pixel. The emissive element layer EMIL may further include a light-emitting element of white sub-pixel. The emissive element layer EMIL in each of the sub-pixels may have a structure in which a light-emitting element and a color filter are stacked. The light-emitting elements EL in the emissive element layer EMIL may be covered with a multi-protective layer including an organic film and an inorganic film.

The encapsulation layer ENC covers the emissive element layer EMIL to seal the circuit layer CIR and the emissive element layer EMIL. The encapsulation layer ENC may also have a multi-insulating film structure in which an organic film and an inorganic film are alternately stacked. The inorganic film blocks permeation of moisture and oxygen. The organic film planarizes the surface of the inorganic film. When the organic film and the inorganic film are stacked in multiple layers, the movement path of moisture and oxygen becomes longer compared to a single layer, so that the penetration of moisture and oxygen that affect the emissive element layer EMIL may be effectively blocked.

A touch sensor layer, omitted in this drawing, may be formed on the encapsulation layer ENC, and a polarizer or a color filter layer may be disposed thereon. The touch sensor layer may include capacitive touch sensors that sense a touch input based on the change in capacitance before and after the touch input. The touch sensor layer may include metal wire patterns and insulating films that form the capacitance of the touch sensors. The insulating films may insulate portions where the metal wire patterns are intersected, and may planarize the surface of the touch sensor layer. The polarizer may improve visibility and contrast ratio by converting the polarization of external light reflected by metals in the touch sensor layer and the circuit layer. The polarizer may be implemented as a polarizer or a circular polarizer in which a linear polarizer and a phase retardation film are bonded. A cover glass may be adhered to the polarizer.

The color filter layer may include red, green, and blue color filters. The color filter layer may further include a black matrix pattern. The color filter layer may replace the polarizer and increase the color purity of an image reproduced in the pixel array by absorbing a portion of the wavelength of the light reflected from the circuit layer and the touch sensor layer.

The power supply 140 generates a direct current (DC) voltage (or a constant voltage) for driving the pixel array of the display panel 100 and the display panel driving circuit. The DC-DC converter may include a charge pump, a regulator, a buck converter, a boost converter, and the like. The power supply 140 may generate the constant voltages such as a gamma reference voltage VGMA, a gate-on voltage VGH, a gate-off voltage VGL, a pixel driving voltage EVDD, a pixel base voltage EVSS, an initialization voltage Vinit, a reference voltage Vref, and the like by adjusting the level of a DC input voltage applied from a host system 200. The gamma reference voltage VGMA is supplied to the data driver 110. The gate-on voltage VGH and the gate-off voltage VGL are supplied to a level shifter 150 and a gate driver 120.

Constant voltages such as the pixel driving voltage EVDD, the pixel base voltage EVSS, the initialization Vinit, and the reference voltage Vref are supplied to the pixels 101 via the power lines commonly connected to the pixels 101.

The power supply 140 may output a constant voltage Vdc that is applied to the stabilization capacitor Ca shown in FIG. 3. The constant voltage Vdc may be a separate constant voltage, or may be replaced by a voltage such as another constant voltage applied to the pixel circuit, for example, a pixel driving voltage EVDD.

The display panel driving circuit writes the pixel data of the input image to the pixels of the display panel 100 under the control of the timing controller 130.

The display panel driving circuit includes the data driver 110 and the gate driver 120. The display panel driving circuit may further include a de-multiplexer array 112 disposed between the data driver 110 and the data lines 102.

The de-multiplexer array 112 sequentially supplies a data voltage output from channels of the data driver 110 to the data lines 102 using a plurality of de-multiplexers (DEMUX). A de-multiplexer may include a multiple of switch elements disposed on the display panel 100. When the de-multiplexer is disposed between the output terminals of the data driver 110 and the data lines 102, the number of the channels of the data driver 110 may be reduced. The de-multiplexer array 112 may be omitted.

The display panel driving circuit may further include a touch sensor driver for driving touch sensors. The touch sensor driver is omitted from FIG. 1. The data driver 110 and the touch sensor driver may be integrated into one drive IC (Integrated Circuit). In mobile devices or wearable devices, the timing controller 130, the power supply 140, the data driver 110, and the like may be integrated into one drive IC.

The display panel driving circuit may operate in a low-speed driving mode under the control of the timing controller 130. In the low-speed driving mode, the power consumption of the display panel 100 and the display panel driving circuit may be reduced, allowing the display device to drive at low power. The low-speed driving mode may be set to reduce the power consumption of the display device when the input image does not change for a predetermined number of frames as a result of analyzing the input image. In the low-speed driving mode, the power consumption in the display panel driving circuit and the display panel 100 may be reduced by lowering a frame frequency at which the pixel data is written to the pixels, that is, a refresh rate, when still images are inputted for a predetermined time or longer. The low-speed driving mode is not limited to a case where the still images are inputted. For example, when the display device operates in a standby mode or when a user command or an input image is not inputted to the display panel driving circuit for a predetermined time or longer, the display panel driving circuit may operate in the low-speed driving mode.

The data driver 110 receives the pixel data of the input image received as a digital signal from the timing controller 130 and outputs the data voltage. The data driver 110 converts the pixel data of the input image into a gamma compensation voltage at each frame period in a normal driving mode using a digital-to-analogue converter (DAC) and outputs the data voltage Vdata. The data driver 110 converts the pixel data of the input image into the gamma compensation voltage to output the data voltage Vdata using the DAC only in a refresh frame in the low-speed driving mode, and stops its operation in the hold frame to not output the data voltage. In the low-speed driving mode, the pixels 101 charge a pixel data voltage in the refresh frame and maintain a previous data voltage in the hold frame.

The gamma reference voltage VGMA is divided by a voltage divider circuit into the gamma compensation voltage for each grayscale. The gamma compensation voltage for each grayscale is provided to the DAC in the data driver 110. The data voltage Vdata is outputted through an output buffer from each of the channels of the data driver 110.

The gate driver 120 may be implemented as a gate in panel (GIP) circuit formed in the circuit layer CIR on the display panel 100 together with the TFT array of the pixel array and wirings. The gate driver 120 may be disposed on a bezel area BZ, which is the non-display area of the display panel 100, or may be distributed in the pixel array in which an input image is reproduced.

The gate driver 120 may be disposed in the non-display area (such as the bezel area BZ) on one or both sides of the display panel 100 with the display area of the display panel interposed therebetween and may supply a gate pulse to the gate lines 103 in a single feeding method or a double feeding method. The gate driver 120 sequentially outputs pulses of the gate signals to the gate lines 103 under the control of the timing controller 130. The gate driver 120 may sequentially supply the gate signals to the gate lines 103 by shifting the gate signals using one or more shift registers.

The timing controller 130 may receive digital video data DATA of the input image and a timing signal synchronized therewith from the host system 200. The timing signal may include a vertical synchronization signal Vsync, a horizontal synchronization signal Hsync, a clock CLK, and a data enable signal DE. A vertical period and a horizontal period may be known by a method of counting the data enable signal DE, and thus the vertical synchronization signal Vsync and the horizontal synchronization signal Hsync may be omitted. The data enable signal DE has an interval of one horizontal period (1H).

The host system 200 may be any one of a television (TV) system, a tablet computer, a notebook computer, a navigation system, a personal computer (PC), a home theater system, a mobile device, a wearable device, or an in-vehicle system. The host system 200 may scale an image signal from a video source to match the resolution of the display panel 100, and may transmit it to the timing controller 130 together with the timing control signal.

The timing controller 130 multiplies an input frame frequency X by i and controls the operation timing of the display panel driving circuit at a frame frequency Xi Hz (where i is a natural number). The input frame frequency is 60 Hz in a National Television Standards Committee (NTSC) system and 50 Hz in a Phase-Alternating Line (PAL) system.

The host system 200 or the timing controller 130 may vary the refresh rate or the frame frequency to match the movement or content characteristics of the input image, or may vary the refresh rate or the frame frequency based on the content of the input image.

The timing controller 130 reduces a frequency of refresh frames at which the pixel data is written to the pixels in the low-speed driving mode, compared to the normal driving mode. For example, the frequency of the refresh frames at which the pixel data is written to the pixels in the normal driving mode may be any one of frequencies greater than 60 Hz, such as 60 Hz, 120 Hz, 144 Hz, 240 Hz, and the refresh frame frequency in the low-speed driving mode may be a lower frequency than that in the normal driving mode. The timing controller 130 may set multiple hold frames after the refresh frames to lower the refresh rate of the pixels in the low-speed driving mode, thereby lowering the driving frequency of the display panel driving circuit and the pixels.

The timing controller 130 generates a data timing control signal for controlling the operation timing of the data driver 110, a MUX control signal for controlling the operation timing of the de-multiplexer array 112, and a gate timing control signal for controlling the operation timing of the gate driver 120, based on the timing signals received from the host system 200. The timing controller 130 synchronizes the data driver 110, the de-multiplexer array 112, the touch sensor driver, and the gate driver 120 by controlling the operation timing of the display panel driving circuit.

The MUX control signal and the gate timing control signal outputted from timing controller 130 may be input to the de-multiplexer array 112 and the gate driver 120 through the level shifter 150. The level shifter 150 may receive the gate timing control signal to generate a start pulse and a shift clock. The start pulse and the shift clock outputted from the level shifter 150 may swing between the gate-on voltage VGH and the gate-off voltage VGL and may be inputted to the shift register of the gate driver 120 via clock lines.

Each of the pixels 101 includes at least a sub-pixel of a first color, a sub-pixel of a second color, and a sub-pixel of a third color. Each of the sub-pixels of the first to third colors includes a driving element having a first electrode connected to a first node, a gate electrode connected to a second node, and a second electrode connected to a third node and supplying current to the light-emitting element. Further, each of the sub-pixels of the first to third colors includes a stabilization capacitor connected between a constant voltage node to which a constant voltage is applied and the third node. The capacitance of the stabilization capacitors is set differently for each color of the sub-pixels. These features will be described in detail in the following embodiments.

FIG. 3 is a diagram illustrating example stabilization capacitors connected to sub-pixels.

As shown in FIG. 3, sub-pixels R, G, and B are connected to data lines DL1, DL2, and DL3 to which data voltages Vdata(R), Vdata(G), and Vdata(B) are applied, respectively, and to one or more gate lines GL to which gate signals GATE are applied.

The red sub-pixel R includes a first stabilization capacitor Ca1. The green sub-pixel G includes a second stabilization capacitor Ca2. The blue sub-pixel B includes a third stabilization capacitor Ca3.

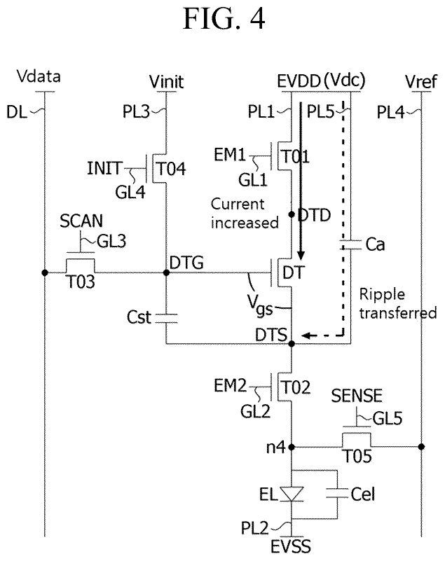

The stabilization capacitors Ca1, Ca2, and Ca3 may be connected between a node between a driving element DT and the light-emitting element EL, and a constant voltage node to which a constant voltage Vdc is applied, as shown in FIGS. 4 to 6.

The stabilization capacitors Ca1, Ca2, and Ca3 reduce a loss of the data voltage of the pixel data by increasing the transfer rate of the data voltage when the data voltage is applied to a storage capacitor of the pixel circuit and a gate electrode of the driving element.

The stabilization capacitors Ca1, Ca2, and Ca3 formed in the sub-pixels R, G, and B, respectively, may be designed with the same capacitance within a pixel 101 having the limited size. In this case, the loss of the data voltage may occur because the stabilization capacitor (such as the stabilization capacitor Ca3) in a sub-pixel that requires a large current, such as the blue sub-pixel B, has insufficient capacitance.

The current at which the light-emitting elements in the sub-pixels R, G, and B may emit light may vary from color to color. For example, the current for driving the sub-pixels normally may be decreased in the order of the blue sub-pixel B, the green sub-pixel G, and the red sub-pixel R. For example, the currents for driving the red sub-pixel R, the green sub-pixel G, and the blue sub-pixel B at a color temperature of 4500K may be 60 to 70 [nA] for the red sub-pixel R, 70 to 80 [nA] for the green sub-pixel G, and 150 to 160 [nA] for the blue sub-pixel B when these sub-pixels are emitted at 1600 nits.

Since the amount of the data voltage lost in the sub-pixels is large when the stabilization capacitors Ca1, Ca2, and Ca3 have the same capacitance, the voltage level of the data voltage output from the data driver 110 should be higher and the voltage range between the minimum voltage and the maximum voltage of the data voltage should be larger. These may increase the size and cost of a drive IC in which the data driver 110 is integrated, as well as increase the power consumption and heat generation of the drive IC.

Therefore, as shown in FIG. 4, in the case of a pixel circuit including a switch element T02 between the driving element DT and the light-emitting element EL which is switched on/off according to an emission control signal (such as an second emission control signal EM2), the capacitance of the stabilization capacitors Ca1, Ca2, and Ca3 may be set differently for each color of the sub-pixels R, G, and B in response to different currents in the sub-pixels R, G, and B.

For example, the capacitance of the third stabilization capacitor Ca3 is larger than that of the first and second stabilization capacitors Ca1 and Ca2, and the capacitance of the second stabilization capacitor Ca2 is larger than that of the first stabilization capacitor Ca1. That is, the capacitance of the stabilization capacitors Ca1, Ca2, and Ca3 is increased in the order of the red sub-pixel R, the green sub-pixel G, and the blue sub-pixel B. In one example, the capacitance of the stabilization capacitors Ca1, Ca2, and Ca3 may be designed to be, but not limited to, Ca1=138 [fF], Ca2=160 [fF], and Ca3=225 [fF].

In another embodiment, in the case of a pixel circuit without a switch element between the driving element DT and the emitting element EL, the capacitance of the stabilization capacitors Ca1, Ca2, and Ca3 may be set differently for each color of the sub-pixels, taking into account the aperture ratio of the sub-pixels R, G, and B and the capacitance of the capacitor of the light-emitting element EL. In this case, it is preferable to design the stabilization capacitors Ca1, Ca2, and Ca3 to have larger capacitances in the order of the red sub-pixel R, the green sub-pixel G, and the blue sub-pixel B.

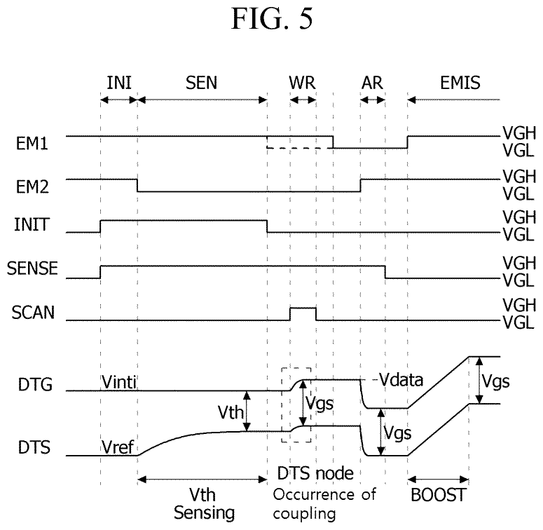

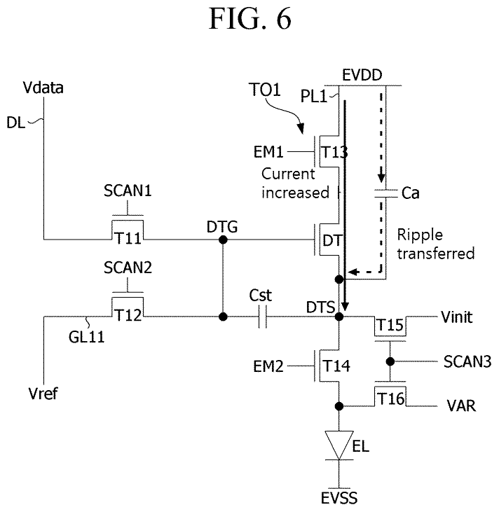

FIG. 4 is a circuit diagram illustrating a pixel circuit according to an example embodiment of the present disclosure. FIG. 5 is a waveform diagram illustrating gate signals applied to the pixel circuit shown in FIG. 4 and voltages of main nodes. FIG. 6 is a circuit diagram illustrating a pixel circuit according to another example embodiment of the present disclosure.

As shown in FIGS. 4 and 5, the pixel circuit includes a light-emitting element EL, a driving element DT driving the light-emitting element EL, a plurality of switch elements T01 to T05, a storage capacitor Cst, a capacitor Cel of the light-emitting element EL and a stabilization capacitor Ca. The driving element DT and the switch elements T01 to T05 may be implemented as an n-channel oxide TFT.

The pixel circuit is connected to a data line DL to which a data voltage Vdata of pixel data is applied, and to gate lines GL1 to GL5 to which gate signals EM1, EM2, INIT, SCAN, and SENSE are applied. The pixel circuit is connected to the power nodes to which DC voltages (or constant voltages) are applied, such as a first constant voltage node PL1 to which a pixel driving voltage EVDD is applied, a second constant voltage node PL2 to which a pixel base voltage EVSS is applied, a third constant voltage node PL3 to which an initialization voltage Vinit is applied, a fourth constant voltage node PL4 to which a reference voltage Vref is applied, and a fifth constant voltage node PL5 to which a constant voltage Vdc is applied. On the display panel 100, the power lines to which the constant voltage nodes are connected may be commonly connected to all pixels. The constant voltage Vdc may be replaced by the pixel driving voltage EVDD. In this case, the fifth constant voltage node PL5 may be omitted because the stabilization capacitor Ca is connected to the first constant voltage node PL1 to which the pixel driving voltage EVDD is applied.

A voltage level of each of the constant voltages EVDD, EVSS, Vinit, and Vref applied to the pixel circuit may be set in consideration of the voltage margin for operation in the saturation region of the driving element DT. The voltage levels of the constant voltages EVDD, EVSS, Vinit, and Vref may be set in the condition of EVDD>Vref>Vinit>EVSS. The constant voltage Vdc applied to the stabilization capacitor Ca may be set to a voltage level greater than or equal to the reference voltage Vref.

The gate signals EM1, EM2, INIT, SCAN, and SENSE include pulses that swing between a gate-on voltage VGH and a gate-off voltage VGL. The gate-on voltage VGH may be set to a voltage level higher than the pixel driving voltage EVDD, and the gate-off voltage VGL may be set to a voltage level lower than the pixel base voltage.

The gate signals INIT, SENSE, SCAN, EM1, and EM2 include a first emission control signal (hereinafter referred to as “EM signal”) EM1, a second EM signal EM2, a first scan signal SCAN, a second scan signal INIT, and a third scan signal SENSE. The first EM signal EM1 may be interpreted as a first gate signal, the second EM signal EM2 may be interpreted as a second gate signal, the first scan signal SCAN may be interpreted as a third gate signal, the second scan signal INIT may be interpreted as a fourth gate signal, and the third scan signal SENSE may be interpreted as a fifth gate signal.

The pixel circuit disposed in each of the sub-pixels may be driven in the following order: an initialization period INI, an sensing period SEN, a data writing period WR, an anode reset period AR, and a light emission period EMIS. The initialization period INI, the sensing period SEN, the data writing period WR, the anode reset period AR, and the light emission period EMIS may be defined by the waveforms of the gate signals EM1, EM2, INIT, SCAN, and SENSE. A boosting period BOOST in which voltages of the second and third nodes DTG and DTS are increased may be included at an initial stage of the light emission period EMIS.

A voltage of the first EM signal EM1 is the gate-on voltage VGH during the initialization period INI, the sensing period SEN, and the light emission period EMIS, and is the gate-off voltage VGL during the anode reset period AR. The voltage of the first EM signal EM1 may be the gate-on voltage VGH or the gate-off voltage VGL during the data writing period WR. A first switch element T01 is turned on in response to the gate-on voltage VGH of the first EM signal EM1 and turned off according to the gate-off voltage VGL of the first EM signal EM1.

A voltage of the second EM signal EM2 is the gate-on voltage VGH during the initialization period INI, the anode reset period AR, and the light emission period EMIS, and is the gate-off voltage VGL during the sensing period SEN and the data writing period WR. A second switch element T02 is turned on in response to the gate-on voltage VGH of the second EM signal EM2 and turned off according to the gate-off voltage VGL of the second EM signal EM2.

A voltage of the first scan signal SCAN is generated as a pulse of the gate-on voltage VGH synchronized with the data voltage Vdata of the pixel data during the data writing period WR, and is the gate-off voltage VGL during the other periods INI, SEN, AR, and EMIS. A third switch element T03 is turned on in response to the gate-on voltage VGH of the first scan signal SCAN and turned off according to the gate-off voltage VGL of the first scan signal SCAN.

A voltage of the second scan signal INIT is generated as a pulse of the gate-on voltage VGH during the initialization period INI and the sensing period SEN, and is the gate-off voltage VGL during the other periods WR, AR, and EMIS. A fourth switch element T04 is turned on in response to the gate-on voltage VGH of the second scan signal INIT and turned off according to the gate-off voltage VGL of the second scan signal INIT.

A voltage of the third scan signal SENSE is the gate-on voltage VGH during the initialization period INI, the sensing period SEN, the data writing period WR, and the anode reset period AR, and is the gate-off voltage VGL during the light emission period EMIS. A fifth switch element T05 is turned on in response to the gate-on voltage VGH of the third scan signal SENSE and turned off according to the gate-off voltage VGL of the third scan signal SENSE.

During the initialization period INI, the initialization voltage Vinit is applied to a second node DTG and the reference voltage Vref is applied to a third node DTS to initialize the storage capacitor Cst and a gate-source voltage Vgs of the driving element DT. During the sensing period SEN, a threshold voltage Vth of the driving element DT is sampled and stored in the storage capacitor Cst. During the data writing period WR, the data voltage Vdata is applied to the second node DTG, and the voltage charged in the storage capacitor Cst is changed to the data voltage Vdata compensated by the threshold voltage of the driving element DT. During the anode reset period AR, the reference voltage Vref is applied to the third node DTS and a fourth node n4 to suppress the fluctuation of the gate-source voltage Vgs of the driving element DT in a low-speed driving mode. During the light emission period EMIS, a current path is formed between the first constant voltage node PL1 and the second constant voltage node PL2, and the light-emitting element EL is driven by the current generated by the gate-source voltage Vgs of the driving element DT. The light-emitting element EL may emit light according to the current from the driving element DT after the boosting period BOOST during the light emission period EMIS.

The driving element DT generates a current according to the gate-source voltage Vgs to drive the light-emitting element EL. The driving element DT includes a first electrode connected to a first node DTD, a gate electrode connected to the second node DTG, and a second electrode connected to the third node DTS.

The storage capacitor Cst is connected between the second node DTG and the third node DTS. The storage capacitor Cst is initialized in the initialization period INI and stores the threshold voltage Vth of the driving element DT in the sensing period SEN. The storage capacitor Cst stores the data voltage Vdata of the pixel data compensated by the threshold voltage Vth of the driving element DT during the data writing period WR, and then maintains the gate-source voltage Vgs of the driving element DT during the anode reset period AR and the light emission period EMIS.

The stabilization capacitor Ca may be connected between the fifth constant voltage node PL5 and the third node DTS, or between the first constant voltage node PL1 and the third node DTS. During the data writing period WR, loss of the data voltage Vdata is avoided.

The first switch element T01 is connected between the first constant voltage node PL1 to which the pixel driving voltage EVDD is applied, and the first node DTD, and is turned on in response to the gate-on voltage VGH of the first EM signal EM1. When the first switch element T01 is turned on, the pixel driving voltage EVDD is applied to the first node DTD. The first switch element T01 is in the off-state when the voltage of the first EM signal EM1 is the gate off voltage VGL. The first switch element T01 includes a first electrode connected to the first constant voltage node PL1, a gate electrode connected to a first gate line GL1 to which the first EM signal EM1 is applied, and a second electrode connected to the first node DTD.

The second switch element T02 is connected between the third node DTS and the fourth node n4 and is turned on in response to the gate-on voltage VGH of the second EM signal EM2. When the second switch element T02 is turned on, the third node DTS is connected to the fourth node n4. The second switch element T02 is in the off-state when the voltage of the second EM signal EM2 is the gate-off voltage VGL. The second switch element T02 includes a first electrode connected to the third node DTS, a gate electrode connected to a second gate line GL2 to which the second EM signal EM2 is applied, and a second electrode connected to the fourth node n4.

The third switch element T03 is connected between the data line DL, to which the data voltage Vdata of the pixel data is applied, and the second node DTG, and is turned on in response to the gate-on voltage VGH of the first scan signal SCAN. When the third switch element T03 is turned on, the data voltage Vdata is applied to the second node DTG. The third switch element T03 is in the off-state when the voltage of the first scan signal SCAN is the gate-off voltage VGL. The third switch element T03 includes a first electrode connected to the data line DL, a gate electrode connected to a third gate line GL3 to which the first scan signal SCAN is applied, and a second electrode connected to the second node DTG.

The fourth switch element T04 is connected between the third constant voltage node PL3, to which the initialization voltage Vinit is applied, and the second node DTG, and is turned on in response to the gate-on voltage VGH of the second scan signal INIT. When the fourth switch element T04 is turned on, the initialization voltage Vinit is applied to the second node DTG. The fourth switch element T04 is in the off-state when the voltage of the second scan signal INIT is the gate-off voltage VGL. The fourth switch element T04 includes a first electrode connected to the third constant voltage node PL3, a gate electrode connected to a fourth gate line GL4 to which the second scan signal INIT is applied, and a second electrode connected to the second node DTG.

The fifth switch element T05 is connected between the fourth constant voltage node PL4, to which the reference voltage Vref is applied, and the fourth node n4, and is turned on in response to the gate-on voltage VGH of the third scan signal SENSE. When the fifth switch element T05 is turned on, the reference voltage Vref is applied to the fourth node n4. The fifth switch element T05 is in the off-state when the voltage of the third scan signal SENSE is the gate-off voltage VGL. The fifth switch element T05 includes a first electrode connected to the fourth constant voltage node PL4, a gate electrode connected to a fifth gate line GL5 to which the third scan signal SENSE is applied, and a second electrode connected to the fourth node n4.

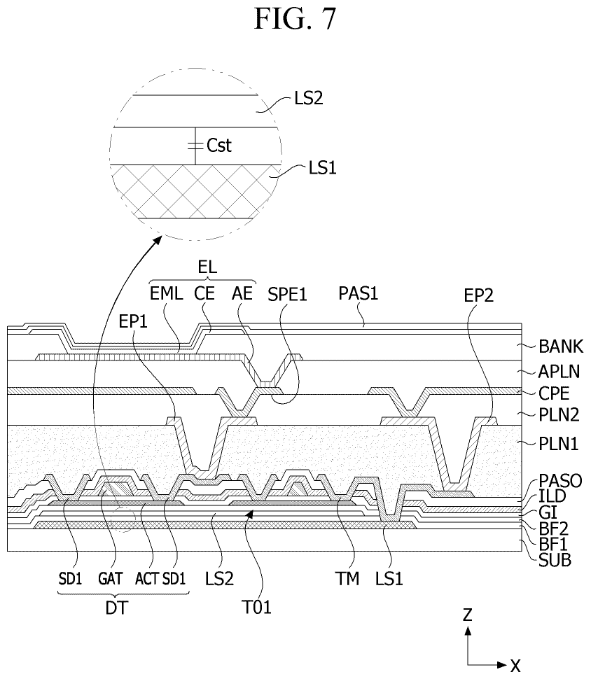

In a circuit having a structure in which a driving voltage wire EP2 (shown in FIG. 7) is connected to the first switch element T01 to which the pixel emission control signal (e.g., EM1) is applied and a stabilization capacitor Ca is formed between the driving voltage wire EP2 and the driving element DT, the driving voltage EVDD by the EM1 for supplying a pulse width modulation (PWM) signal may cause a change in resistance of the driving voltage wire. Accordingly, a ripple due to the change in resistance of the driving voltage wire is transferred through the stabilization capacitor Ca to affect the DTS node, thereby causing problems such as poor threshold voltage sensing, luminance change, poor image, and so on.

This ripple transfer may be equally present not only in a 6T2C structure, as shown in FIGS. 4 and 5, but also in a 7T2C structure, as shown in FIG. 6. As shown in FIG. 6, a pixel circuit includes a driving element DT for driving a light-emitting element EL, a plurality of switch elements T11, T12, T13, T14, T15 and T16 to which a plurality of signals SCAN1, SCAN2, SCAN 3, EM1, and EM2 are applied, a storage capacitor Cst, and a stabilization capacitor Ca. The driving element DT and the switch elements T11 to T16 may be implemented as, but are not limited to, an n-channel transistor. An initialization voltage Vinit can be applied to the switch element 15, and a second initialization voltage VAR can be applied to the switch element 16. A reference voltage Vref can be applied to the switch element 12 via node GL11.

That is, the problem of poor image quality due to the ripple transfer described above may occur in a circuit structure in which the driving voltage wire EP2 (shown in FIG. 7) is connected to the switch element to which the pixel emission control signal (e.g., EM1) is applied and the stabilization capacitor Ca is formed between the driving voltage wire EP2 and the driving element DT.

In contrast, the present disclosure may provide a display panel in which the luminance change due to the ripple transfer are suppressed by reducing the resistance on the driving voltage wire by means of a compensation electrode layer. Accordingly, according to an embodiment, since the resistance on the driving voltage wire is lowered, a display panel with improved EVDD IR Drop (voltage drop) may be implemented.

FIG. 7 is a cross-sectional view of a sub-pixel in an example display panel according to a first embodiment of the present disclosure.

With reference to FIG. 7, a stacked structure of the display area in the display panel is described. Here, a stacking direction may be a direction from the substrate SUB toward each layer on the substrate SUB. For example, the stacking direction may correspond to the ‘Z-axis direction’. And the horizontal direction may correspond to the direction perpendicular to the stacking direction.

In the display panel according to a first embodiment, the display panel includes a substrate SUB, a first light shielding layer LS1, a first buffer layer BF1, a second light shielding layer LS2, a second buffer layer BF2, a driving element DT, a capacitor, a gate insulating film GI, an interlayer dielectric film ILD, a first passivation layer PASO, a metal pattern TM, a first planarization layer PLN1, an electrode pattern EP1, a driving voltage wire EP2, a second planarization layer PLN2, a compensation electrode layer CPE, a third planarization layer APLN, a light-emitting element EL, a bank or bank layer BANK, and a second passivation layer PAS1.

The substrate SUB is a base substrate, which may be made of glass or plastic. For example, the substrate SUB may be formed of a plastic material, such as polyimide (PI), polyethylene terephthalate (PET), polyethylene naphthalate (PEN), polycarbonate (PC), etc.

On the substrate SUB, circuit elements including various signal lines, a driving element DT, a storage capacitor, and the like may be formed for each of the plurality of sub-pixels. The signal lines may include a gate line GL, a data line DL, a first power line (EVDD, driving power wire, or pixel power wire), a second power line (EVSS, auxiliary power line, or common power line), and a reference line.

The first light shielding layer LS1 and the second light shielding layer LS2 may be disposed to overlap the driving element DT. For example, the first light shielding layer LS1 and the second light shielding layer LS2 may be disposed to overlap the active layer ACT of the driving element DT, and in particular, may be disposed to overlap the channel region of the active layer ACT on a plane. The first light shielding layer LS1 and the second light shielding layer LS2 may serve to block external light from entering the active layer ACT.

The first light shielding layer LS1 may be disposed on the substrate SUB. And the second light shielding layer LS2 may be disposed on the first light shielding layer LS1 and the first buffer layer BF1.

The first light shielding layer LS1 may be electrically connected to the metal pattern TM between the substrate SUB and the metal pattern TM. And the second light shielding layer LS2 may be disposed between the first light shielding layer LS1 and the gate electrode GAT of the driving element DT. A storage capacitor Cst and/or a stabilization capacitor may be formed between the first light shielding layer LS1 and the second light shielding layer LS2.

The first buffer layer BF1 may be disposed on the substrate SUB and the first light shielding layer LS1. Further, the second buffer layer BF2 may be disposed on the first buffer layer BF1 and the second light shielding layer LS2.

The first buffer layer BF1 and the second buffer layer BF2 may be formed to cover the respective light shielding layers and auxiliary power wires. The first buffer layer BF1 and the second buffer layer BF2 may be formed by a single layer or stacking a plurality of inorganic films. For example, the first buffer layer BF1 and the second buffer layer BF2 may be formed of a single layer of silicon oxide film (SiOx), silicon nitride film (SiNx), and silicon oxynitride film (SiOxNy). Alternatively, the first buffer layer BF1 and the second buffer layer BF2 may be formed of a multi-film in which at least two films of a silicon oxide film (SiOx), a silicon nitride film (SiNx), and a silicon oxynitride film (SiOxNy) are stacked. The first buffer layer BF1 and the second buffer layer BF2 may be formed on the entire top surface of the substrate SUB to block ions or impurities diffusing from the substrate SUB and to block moisture penetrating through the substrate SUB to the light-emitting element EL.

On the second buffer layer BF2, the driving element DT, the storage capacitor Cst, and the metal pattern TM may be disposed.

The driving element DT may be disposed on the substrate SUB. In addition, the driving element DT may be disposed in each of the plurality of sub-pixels on the first buffer layer BF1 and the second buffer layer BF2.

For example, the driving element DT may include the active layer ACT, a gate electrode GAT overlapping the active layer ACT with the gate insulating film GI therebetween, and a source-drain electrode pattern SD1.

A plurality of switch elements may be formed within the display panel. The plurality of switch elements may be formed on the same layer as the driving element DT. Although a first switch element T01 among a plurality of switch elements is illustrated in the drawing, different switch elements may be illustrated depending on the cutting direction.

The source-drain electrode of the first switch element T01 may be connected to the first light shielding layer LS1 by means of the metal pattern TM. In addition, the source-drain electrode of the first switch element T01 may also be connected to the driving voltage wire EP2 by means of the metal pattern TM.

The active layer ACT of the driving element DT may be made of a silicon-based or oxide-based semiconductor material, and may be formed on the first buffer layer BF1 and the second buffer layer BF2. The active layer ACT may include a channel region overlapping the gate electrode GAT and a source-drain region connected to a source-drain electrode pattern SD1.

The gate insulating film GI may be formed on the active layer ACT. The gate insulating film GI may be disposed on the channel region of the active layer ACT and may function to isolate the active layer ACT and the gate electrode GAT. The gate insulating film GI may be made of an inorganic insulating material, for example, a silicon oxide film (SiOx), a silicon nitride film (SiNx), a silicon oxynitride film (SiOxNy), or a multi-film thereof.

The gate electrode GAT may be formed on the gate insulating film GI. The gate electrode GAT may be disposed to face the active layer ACT, with the gate insulating film GI therebetween. And the gate electrode GAT may be made of a single layer or multiple layers of any one selected from the group consisting of copper (Cu), molybdenum (Mo), aluminum (Al), chromium (Cr), gold (Au), titanium (Ti), nickel (Ni), neodymium (Nd), tantalum (Ta), or tungsten (W), or an alloy thereof.

The interlayer dielectric film ILD may be formed on the first buffer layer BF1 and the second buffer layer BF2. The interlayer dielectric film ILD may cover the gate electrode GAT. The interlayer dielectric film ILD may perform the function of protecting the driving element DT. The interlayer dielectric film ILD may be made of an inorganic insulating material. For example, the interlayer dielectric film ILD may be made of a silicon oxide film (SiOx), a silicon nitride film (SiNx), a silicon oxynitride film (SiOxNy), or a multi-film thereof.

The source-drain electrode pattern SD1 may be electrically connected to the active layer ACT by contacting it through a contact hole that penetrates the interlayer dielectric film ILD. In addition, the first and second source-drain electrode patterns SD1 may penetrate the gate insulating film GI.

Additionally, the metal pattern TM may be formed on the interlayer dielectric film ILD. As described above, the metal pattern TM may penetrate the interlayer dielectric film ILD and the gate insulating film GI. In addition, the metal pattern TM may penetrate up to the second buffer layer BF2. The metal pattern TM may penetrate the interlayer dielectric film ILD, and the first buffer layer BF1 and the second buffer layer BF2 below the interlayer dielectric film ILD. Therefore, the metal pattern TM may be electrically connected to the first light shielding layer LS1 through a contact hole that penetrates the interlayer dielectric film ILD and the first buffer layer BF1 and the second buffer layer BF2 below the interlayer dielectric film ILD. And the metal pattern TM may be connected to the first switch element T01 and the first constant voltage node (PL1 in FIG. 4) to which the pixel driving voltage EVDD is applied. The metal pattern TM may be a wire to which the driving voltage EVDD is applied or a connecting electrode connected to such a wire. In addition, the metal pattern TM may be a source and/or drain electrode of the first switch element. In the following, the metal pattern TM is described as a wire that extends in a direction different from the driving voltage wire EP2 described below and to which the driving voltage is applied.

The source-drain electrode pattern SD1 and the metal pattern TM may be formed on the same layer. Furthermore, the source-drain electrode pattern SD1 and the metal pattern TM may be made of the same material. The source-drain electrode pattern SD1 and the metal pattern TM may be formed simultaneously using the same process. The source-drain electrode pattern SD1 and the metal pattern TM may each be formed of a single layer or multiple layers. When the source-drain electrode pattern SD1 and the metal pattern TM are each formed of a single layer, they may be made of any one selected from the group consisting of molybdenum (Mo), aluminum (Al), chromium (Cr), gold (Au), titanium (Ti), nickel (Ni), neodymium (Nd), or copper (Cu), or an alloy thereof. Furthermore, when the source-drain electrode pattern SD1 and the metal pattern TM are each formed of a multi-layer, they may be a double layer of molybdenum/aluminum-neodymium, molybdenum/aluminum, titanium/aluminum, or copper/molytitanium. Alternatively, the source-drain electrode pattern SD1 and the metal pattern TM may each be made of a triple layer of molybdenum/aluminum-neodymium/molybdenum, molybdenum/aluminum/molybdenum, titanium/aluminum/titanium, or molybdenum/copper/molybdenum. However, the above description is not limited thereto, the source-drain electrode pattern SD1 and the metal pattern TM may each be formed of a multilayer of any one selected from the group consisting of molybdenum (Mo), aluminum (Al), chromium (Cr), gold (Au), titanium (Ti), nickel (Ni), neodymium (Nd), or copper (Cu), or an alloy thereof.

The first passivation layer PASO may be disposed on the driving element DT and the metal pattern TM. The first passivation layer PASO may be referred to as a protective layer.

The first passivation layer PASO may be formed to cover the driving element DT and the metal pattern TM. The first passivation layer PASO may protect the driving element DT and may be made of an inorganic insulating material. For example, the first passivation layer PASO may be formed of silicon oxide (SiOx), silicon nitride (SiNx), or a multi-film thereof.

The first planarization layer PLN1 may be disposed on the first passivation layer PASO. The first planarization layer PLN1 may be disposed on the driving element DT and the first and second source-drain electrode patterns SD1.

The electrode pattern EP1 may be disposed on the first planarization layer PLN1. The electrode pattern EP1 may be connected to one of the first and second source-drain electrode patterns SD1 of the two driving elements DT through a contact hole in the first planarization layer PLN1. That is, the electrode pattern EP1 may penetrate the first planarization layer PLN1 and be connected to the source-drain electrode pattern SD1.

The driving voltage wire EP2 may be disposed on the first planarization layer PLN1. The driving voltage wire EP2 may be connected to the metal pattern TM through a contact hole in the first planarization layer PLN1. That is, the driving voltage wire EP2 may penetrate the first planarization layer PLN1 and be connected to the metal pattern TM. The driving voltage wire EP2 may correspond to the driving voltage wire EP2 or a wire within the display panel.

The driving voltage wire EP2 may be spaced apart from the electrode pattern EP1. In addition, the driving voltage wire EP2 may be electrically separated from the electrode pattern EP1.

Furthermore, the driving voltage wire EP2 and the electrode pattern EP1 may be disposed on the same layer and formed by the same material or process.

The second planarization layer PLN2 may be disposed on the electrode pattern EP1 and the driving voltage wire EP2. The first planarization layer PLN1, the second planarization layer PLN2, and the third planarization layer APLN described later may be made of at least one of organic materials, such as photo acrylic, polyimide, benzocyclobutene resin, and acrylate resin.

In the present disclosure, the compensation electrode layer CPE may be disposed on a different layer from the driving voltage wire EP2. The compensation electrode layer CPE may be located in a different layer from the first planarization layer PLN1 on which the driving voltage wire EP2 is formed. The compensation electrode layer CPE may be disposed on top of the electrode pattern EP1 (or the driving voltage wire) and the driving voltage wire EP2, and may be electrically connected to the driving voltage wire EP2.

The compensation electrode layer CPE may lower the resistance on the driving voltage wire EP2. That is, since the relatively wide compensation electrode layer CPE is electrically connected to the driving voltage wire EP2, the resistance on the driving voltage wire EP2 may be relatively reduced. Therefore, even if a pulse signal is repeatedly applied to the first switch element T01, the fluctuation range of the driving voltage may become smaller.

The third planarization layer APLN may be located on the compensation electrode layer CPE. However, this is not limited thereto, the position of the third planarization layer APLN may vary according to the position of the compensation electrode layer CPE. For example, the third planarization layer APLN may be positioned at a layer other than the top of the first planarization layer PLN1. The third planarization layer APLN may be positioned on the electrode pattern EP1 or on the second planarization layer PLN2. That is, the third planarization layer APLN may be positioned between the compensation electrode layer CPE and the bank BANK. Alternatively, the third planarization layer APLN may be positioned between the substrate SUB and the second light shielding layer LS2 (or the first buffer layer BF1). In this embodiment, the third planarization layer APLN may be positioned on the electrode pattern EP1 or on the second planarization layer PLN2.

As described above, the compensation electrode layer CPE may be disposed on top of the second planarization layer PLN2. And the compensation electrode layer CPE may be connected to the driving voltage wire EP2 through the contact hole of the second planarization layer PLN2.

The third planarization layer APLN may be disposed on the compensation electrode layer CPE and the second planarization layer PLN2. On the third planarization layer APLN, the light-emitting element EL may be disposed.

The light-emitting element EL may include an anode electrode AE, an emission layer EML, and a cathode electrode CE arranged sequentially in the stacking direction. That is, the light-emitting element EL may be formed by the anode electrode AE, the emission layer EML, and the cathode electrode CE. The emission layer EML may include an organic film.

The anode electrode AE may be disposed on the third planarization layer APLN. The anode electrode AE may be electrically connected to the electrode pattern EP1 through a connecting electrode portion SPE1. The connecting electrode portion SPE1 may be formed simultaneously with the formation of the compensation electrode layer CPE. Accordingly, the connecting electrode portion SPE1 may have the same material and thickness as the compensation electrode layer CPE. The connecting electrode portion SPE1 may be spaced apart and electrically isolated from the compensation electrode layer CPE.

The emission layer EML may be disposed on the anode electrode AE. The bank BANK may cover a portion of the anode electrode AE and have an open shape in an area corresponding to a light-emitting area. For example, the bank BANK may have an aperture in the area corresponding to the light-emitting area. And a portion of the anode electrode AE may be exposed by an aperture (an open portion) of the bank BANK. At the aperture of the bank BANK, the emission layer EML may be in contact with the anode electrode AE. The emission layer EML may also be in contact with the upper cathode electrode CE at the aperture.

The second passivation layer PAS1 is disposed on the cathode electrode CE and may be disposed closest to the light-emitting element EL. The second passivation layer PAS1 may be formed of an inorganic insulating material capable of low-temperature deposition. For example, the second passivation layer PAS1 may be formed of silicon nitride (SiNx), silicon oxide (SiOx), silicon oxynitride (SiON), or aluminum oxide (Al₂O₃). Since the second passivation layer PAS1 is deposited in a low-temperature atmosphere, the second passivation layer PAS1 may prevent or reduce damage to the emission layer EML, which contains an organic material that is vulnerable to a high-temperature atmosphere, during the deposition process.

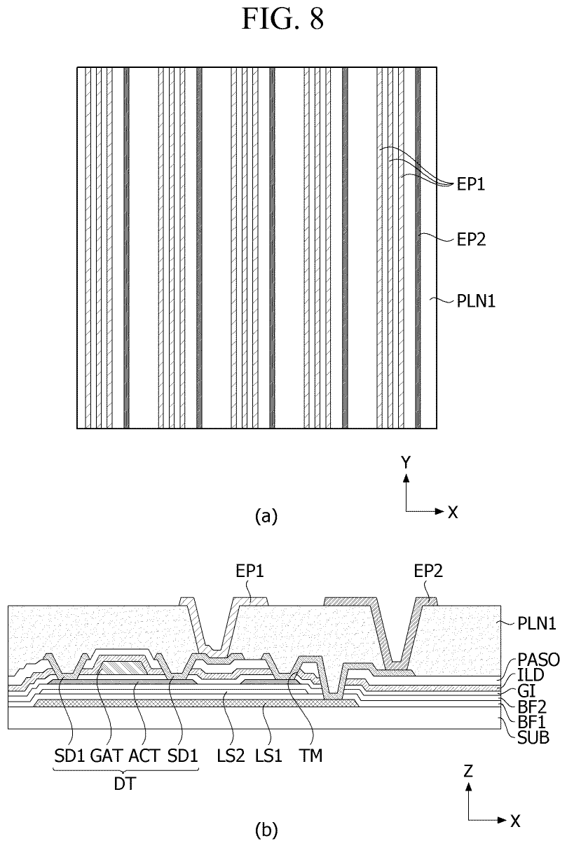

FIG. 8 shows (a) a plan view and (b) a cross-sectional view of an example display panel according to a first embodiment, in which up to the electrode pattern and the driving voltage wire are stacked.

As shown in (a) of FIG. 8, the electrode pattern EP1 and the driving voltage wire EP2 may extend in a second direction (Y-axis direction). In addition, the electrode pattern EP1 and the driving voltage wire EP2 may be spaced apart from each other in a first direction (X-axis direction) intersecting the second direction. The electrode pattern EP1 and the driving voltage wire EP2 may be electrically separated from each other. For example, since the electrode pattern EP1 is connected to each of the first to third sub-pixels that constitute each pixel, three electrode patterns EP1 may be disposed for each pixel.

The electrode pattern EP1 and the driving voltage wire EP2 may be disposed on the first planarization layer PLN1. The electrode pattern EP1 and the driving voltage wire EP2 may be formed of the same material on the first planarization layer PLN1.

Furthermore, the electrode pattern EP1 and the driving voltage wire EP2 may be located within the contact hole of the first planarization layer PLN1. The electrode pattern EP1 may penetrate the first planarization layer PLN1 and be connected to the source-drain electrode pattern SD1. The driving voltage wire EP2 may penetrate the first planarization layer PLN1 and be connected to the metal pattern TM. The metal pattern TM may be electrically connected to the pixel circuit through a conductorized semiconductor layer. The cross-sectional view in FIG. 7 and the cross-sectional view in (b) of FIG. 8 may have different cutting directions. FIG. 7 may be a cross-section illustrating a portion where the first switch element and a voltage connection wire are connected, and (b) of FIG. 8 may be a cross-section cropped so that only a voltage connection wire is visible without the first switching element being visible.

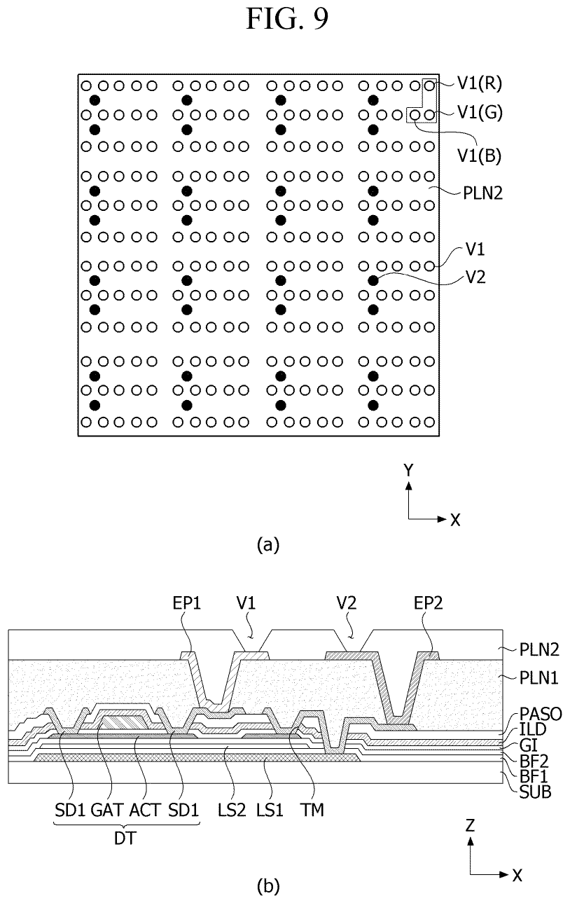

FIG. 9 shows (a) a plan view and (b) a cross-sectional view of an example display panel according to a first embodiment, in which up to the second planarization layer is stacked.

The second planarization layer PLN2 may be disposed on the first planarization layer PLN1, the electrode pattern EP1, and the driving voltage wire EP2. The second planarization layer PLN2 may cover a portion of the electrode pattern EP1 and the driving voltage wire EP2.

The second planarization layer PLN2 may include a first via V1 exposing the electrode pattern EP1. Furthermore, the second planarization layer PLN2 may include a second via V2 exposing the driving voltage wire EP2.

The second planarization layer PLN2 may include a plurality of first vias V1 and second vias V2. The first via V1 and the second via V2 may be spaced apart from each other. For example, the first via V1 and the second via V2 may not overlap each other in the stacking direction. In other words, the first via V1 and the second via V2 may be disposed to be misaligned in the stacking direction. The first via V1 and the second via V2 may also be spaced apart from each other in the horizontal direction.

The first via V1 may be positioned corresponding to each of the sub-pixels R, G, and B. For example, one first via V1(R) or V1(G) or V1(B) may be located corresponding to one sub-pixel. In contrast, the second via V2 may be located regardless of each sub-pixel. The second via V2 is spaced apart from the first via V1 and may not overlap the electrode pattern EP1 in the stacking direction. That is, the first via V1 may expose the electrode pattern EP1, and the second via V2 may expose the driving voltage wire EP2.

The compensation electrode layer CPE is electrically connected to the metal pattern TM through the second via V2, and the second via V2 may be located in an area at which a jumping structure can be formed between the driving voltage wire EP2 and the compensation electrode layer CPE.

There may be a plurality of second vias V2. The plurality of second vias V2 may be disposed along the driving voltage wire EP2. In other words, the plurality of second vias V2 may be positioned corresponding to the driving voltage wire EP2 shown in (a) and (b) of FIG. 9. The plurality of second vias V2 are located on the driving voltage wire EP2 and may be disposed along an extension direction of the driving voltage wire EP2. For example, if the driving voltage wire EP2 extends along the column, a plurality of second vias V2 may be disposed so as to be spaced apart or extended along the column.

The driving voltage wire EP2 may be exposed by the second via V2. And corresponding to this arrangement of the driving voltage wire EP2, the second vias V2 may also be disposed on the driving voltage wire EP2 to be spaced apart for each pixel. However, the second via V2 is a contact hole for connection between the driving voltage wire EP2 and the compensation electrode layer, and may not be disposed at each driving voltage wire EP2 extending in the column direction. For example, it may be positioned to overlap, in the stacking direction, at least one of the first driving voltage wire and the second driving voltage wire that are adjacent.

In contrast, since the first via V1 needs to be connected to the driving element (the source-drain electrode pattern) of each sub-pixel in the pixel, the first via V1 may be positioned to overlap, in the stacking direction, the electrode pattern EP1 formed on each sub-pixel.

In addition, the plurality of second vias V2 may be located between the first vias V1 spaced apart in one direction or the other direction. The first via V1 and the second via V2 may overlap at least partially in the other direction. Furthermore, the second via V2 may be disposed symmetrically on the display panel with respect to the center of the display panel or the bisector of one direction. As a result, since the connection point between the compensation electrode layer and the driving voltage wire EP2 is increased, the concentration of the resistance in one area may be improved.

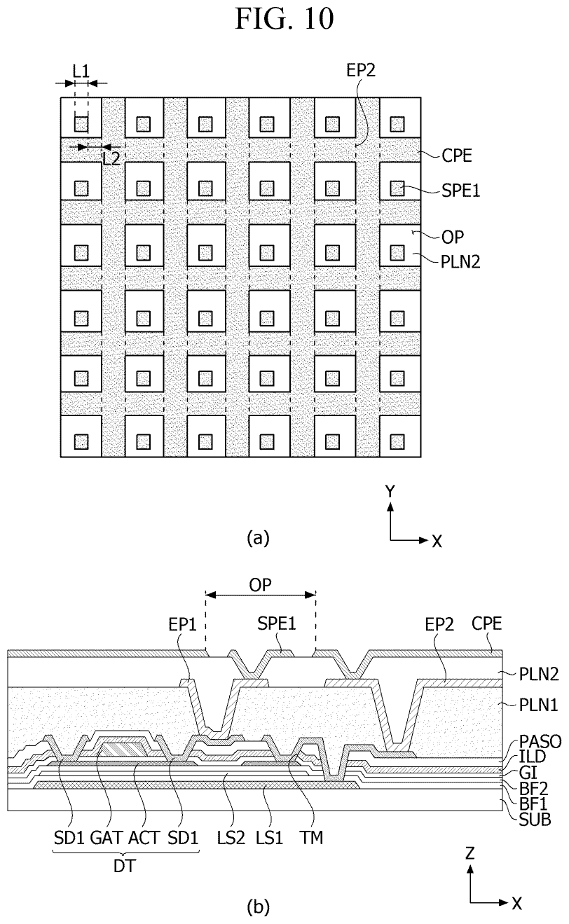

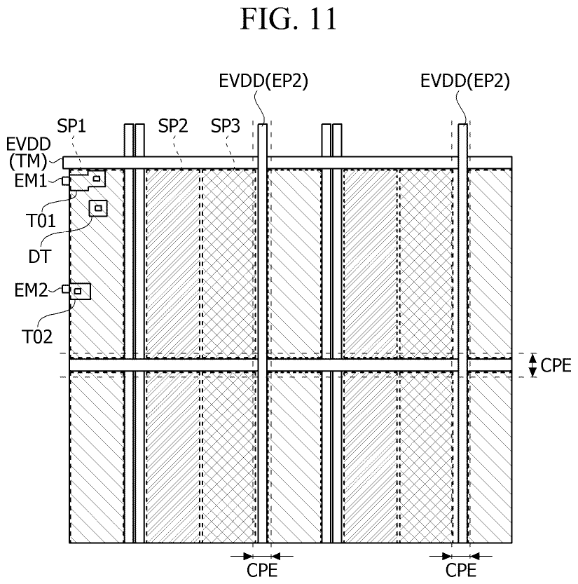

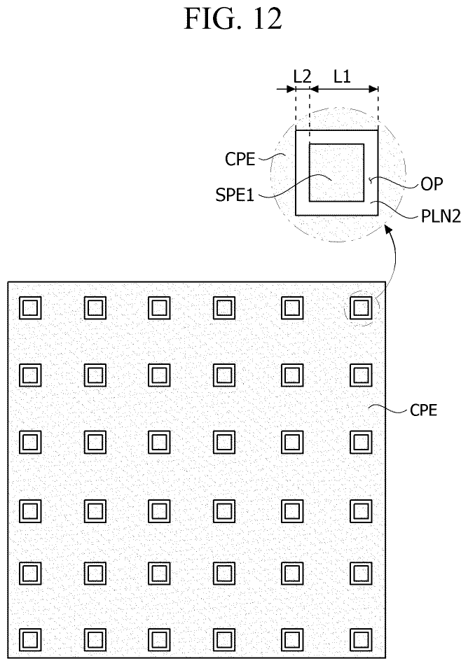

FIG. 10 shows (a) a plan view and (b) a cross-sectional view of an example display panel in which up to the compensation electrode layer is stacked according to the first embodiment, FIG. 11 is a plan view of the display panel and the compensation electrode layer according to the first embodiment, and FIG. 12 is a plan view of a compensation electrode layer according to another example.

As shown in (a) of FIG. 10, the compensation electrode layer CPE may have a plurality of aperture regions OP and a mesh shape surrounding the plurality of aperture regions OP. The connecting electrode portion SPE1 may be disposed within each of the plurality of aperture regions OP. The connecting electrode portion SPE1 may be electrically isolated from the compensation electrode layer CPE.

The compensation electrode layer CPE may be disposed on the second planarization layer PLN2. The compensation electrode layer CPE is disposed within the first and second vias of the second planarization layer PLN2, so that a portion thereof may penetrate the second planarization layer PLN2.

The connecting electrode portion SPE1 may be positioned corresponding to the electrode pattern EP1. Although one connecting electrode portion SPE1 is illustrated within the aperture regions OP in the drawing, a plurality of connecting electrode portions SPE1 corresponding to the sub-pixels may be disposed within the aperture regions OP. For example, when an aperture region OP corresponds to one pixel in the compensation electrode layer CPE formed extending in the row and column directions, the number of connection electrode portions SPE1 corresponding to the number of sub-pixels may be located in the aperture regions OP.

The connecting electrode portion SPE1 may at least partially overlap the electrode pattern EP1 in the stacking direction. The connecting electrode portion SPE1 may be disposed in the first via of the second planarization layer PLN2. Accordingly, the connecting electrode portion SPE1 may be in contact with the electrode pattern EP1. The connecting electrode portion SPE1 may be a jumping electrode between the anode electrode and the electrode pattern EP1 for applying the driving signal to each pixel in the display panel.

The compensation electrode layer CPE may penetrate the second planarization layer PLN2. The compensation electrode layer CPE may be disposed inside the second via of the second planarization layer PLN2. Accordingly, the compensation electrode layer CPE may be in contact with the driving voltage wire EP2 through the contact hole (the second via).

The compensation electrode layer CPE may be positioned at least partially to correspond to the driving voltage wire EP2. The compensation electrode layer CPE may at least partially overlap the driving voltage wire EP2 in the stacking direction.

The aperture region OP may be located above the first via and the second via. For example, the aperture region OP may not overlap the first via or the second via in the stacking direction. This may prevent or reduce flatness deterioration.

In another example, the aperture region OP may at least partially overlap the first via and the second via in the stacking direction. With such a configuration, a space other than the connection electrode portion SPE1 may be secured, thereby further increasing the area for the compensation electrode layer CPE.

In addition, the aperture region OP may be disposed to surround the connecting electrode portion SPE1. The aperture region OP may have a closed-loop structure on a plane. Thus, the compensation electrode layer CPE may be physically and electrically separated from the connecting electrode portion SPE1.

The length L1 of the connecting electrode portion SPE1 in one direction and the length L2 of the aperture region OP in one direction may be different from each other. The length of the aperture region OP in one direction may correspond to a separation distance between the connecting electrode portion SPE1 and the compensation electrode layer CPE in one direction.

As shown in (a) of FIG. 10, the length L1 of the connecting electrode portion SPE1 in one direction may be less than the length L2 of the aperture region OP in one direction. This may makes it easier to achieve the electrical separation between the connecting electrode portion SPE1 and the compensation electrode layer CPE. This means that the occurrence of electrical issues such as short circuits may be suppressed.

As shown in FIG. 11, a pixel of the display panel may have a plurality of sub-pixels SP1, SP2, and SP3 spaced apart from each other. The plurality of sub-pixels may include a first sub-pixel SP1, a second sub-pixel SP2, and a third sub-pixel SP3. For example, the first sub-pixel SP1, the second sub-pixel SP2, and the third sub-pixel SP3 may each emit red, blue, and green light, respectively. For example, red (R) light may be emitted from the first sub-pixel SP1. Green (G) light and blue (B) light may be emitted from the second sub-pixel SP2 and the third sub-pixel SP3, respectively. Data signal wire may be located between adjacent sub-pixels.

And the pixel may have first and second switch elements T01 and T02 to which the emission control signals EM1 and EM2 are applied. In addition, the driving element DT may be located in the pixel. For example, the first and second switch elements T01 and T02 and the driving element DT may be located in the first sub-pixel SP1.

Additionally, the driving voltage wire EP2 may be disposed to extend in a column direction. In addition, the metal pattern TM, which is another wire to which the driving voltage EVDD is applied, may be disposed to extend in the row direction. Or they may be disposed in reverse. And the wires TM and EP2 for applying the driving voltage EVDD may be disposed in plural, with a distance from each other.

The wires TM and EP2 applying the driving voltage may intersect in the column direction and the row direction, forming an area corresponding to one pixel or a plurality of sub-pixels (e.g., the first sub-pixel to the third sub-pixel). And each sub-pixel may be connected to the wires TM and EP2 that apply the driving voltage.

In an embodiment, the compensation electrode layer CPE may be formed in a shape corresponding to the metal pattern TM and the driving voltage wire EP2 that apply the driving voltage EVDD.

The metal pattern TM and the driving voltage wire EP2 may be disposed in a mesh shape. And corresponding to the metal pattern TM and the driving voltage wire EP2, the compensation electrode layer CPE may also be disposed to extend in the row direction and the column direction on a plane perpendicular to the stacking direction. That is, the compensation electrode layer CPE may have a mesh shape. In addition, the compensation electrode layer CPE may at least partially overlap the metal pattern TM and the driving voltage wire EP2 in the stacking direction. Moreover, the driving voltage EVDD signal having the same potential may be applied to the metal pattern TM and the driving voltage wire EP2. In this case, a parasitic capacitor may not be formed between the metal pattern TM (or/and the driving voltage wire EP2) and the compensation electrode layer due to the applied same potential.

The compensation electrode layer CPE may have an area equal to or different from that of the driving voltage wire EP2 and the metal pattern TM. When the compensation electrode layer CPE is formed to correspond to the driving voltage wire EP2 and the metal pattern TM, the area of the compensation electrode layer CPE may be substantially the same as the summing area of both the driving voltage wire EP2 and the metal pattern TM.

Furthermore, the compensation electrode layer CPE may be located below the driving voltage wire EP2 and the metal pattern TM, but the area of the compensation electrode layer CPE may be smaller than the area of the driving voltage wire EP2 and the metal pattern TM. Even in this case, no parasitic capacitor may be formed between the metal pattern TM (or/and the driving voltage wiring EP2) and the compensation electrode layer as described above. In addition, the parasitic capacitor may not be formed because the compensation electrode layer CPE does not overlap the electrodes other than the metal pattern TM and the driving voltage wire EP2 located below the compensation electrode layer CPE in the stacking direction. Moreover, a low resistance on the driving voltage wire may be effectively achieved by using the compensation electrode layer CPE.

As shown in FIG. 12, the length L1 of the connecting electrode portion SPE1 in one direction may be larger than the length L2 of the aperture region OP in one direction. The compensation electrode layer CPE may be formed on the entire panel except for an area of the first via or the connecting electrode portion SPE1 of the display panel. In this way, the compensation effect for the resistance on the drive voltage wire EP2 can be maximized.

For example, in the compensation electrode layer CPE, the ratio of the aperture region OP may decrease and the ratio of the compensation electrode layer CPE may increase. The area of the compensation electrode layer CPE may be larger than the area of the connecting electrode portion SPE1. The area of the compensation electrode layer CPE may be further increased on the second planarization layer PLN2.

The compensation electrode layer CPE may include an area that does not overlap the driving voltage wire EP2 and the metal pattern TM. Furthermore, the area of the compensation electrode layer CPE may be larger than the summing area of both the driving voltage wire EP2 and the metal pattern TM.

Thus, a low resistance on the driving voltage wire may be achieved very effectively by increasing the area of the compensation electrode layer CPE. This reduces resistance changes due to the fluctuation in the driving voltage EVDD, thereby effectively suppressing luminance change and poor image.

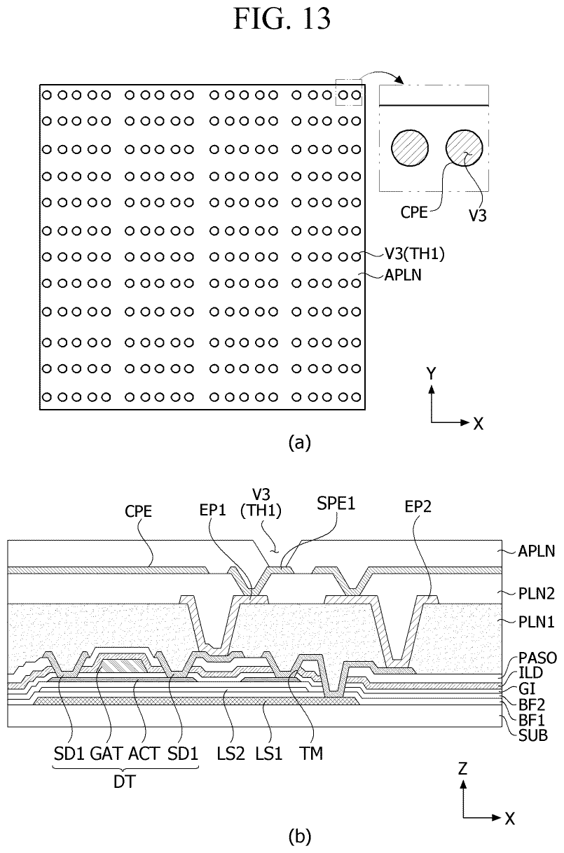

FIG. 13 shows (a) a plan view and (b) a cross-sectional view of an example display panel in which up to the third planarization layer is stacked, according to a first embodiment.

As shown in (b) of FIG. 13, the third planarization layer APLN may be disposed on the compensation electrode layer CPE or the second planarization layer PLN2. Further, the third planarization layer APLN may be disposed between the second planarization layer PLN2 and the light-emitting element. The third planarization layer APLN may cover the compensation electrode layer CPE. This may further improve the flatness on the display panel.

The third planarization layer APLN may include a first through-hole TH1 (or a third via V3). The first through-hole TH1 may overlap the connecting electrode portion SPE1 in the stacking direction. The first through-hole TH1 may at least partially overlap the first via V1 in the stacking direction.

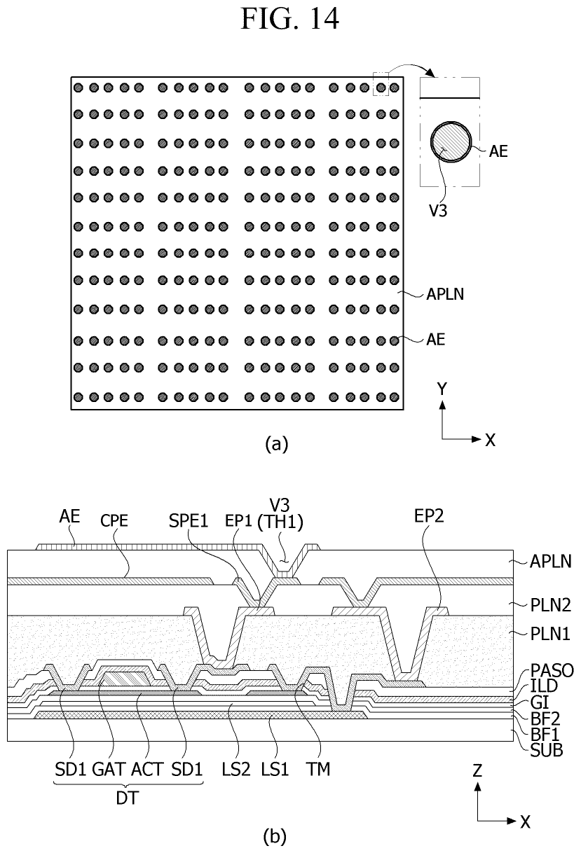

FIG. 14 shows (a) a plan view and (b) a cross-sectional view of an example display panel in which up to the anode electrode is stacked, according to a first embodiment.

As shown in (b) of FIG. 14, the anode electrode AE of the light-emitting element may be disposed in the first through-hole TH1 of the third planarization layer APLN. Accordingly, the connecting electrode portion SPE1 may be electrically connected to the anode electrode AE. Further, the anode electrode AE may be electrically connected to the electrode pattern EP1 and the source-drain electrode pattern SD1 through the connecting electrode portion SPE1.

The anode electrode AE may be disposed within the first through-hole TH1 and may extend outward from the first through-hole TH1. In particular, the anode electrode AE may extend to a lower portion of the fourth via, which is the light-emitting area of the light-emitting element described later. Accordingly, the anode electrode AE may be positioned to overlap the fourth via and the first through-hole TH1 in the vertical direction.

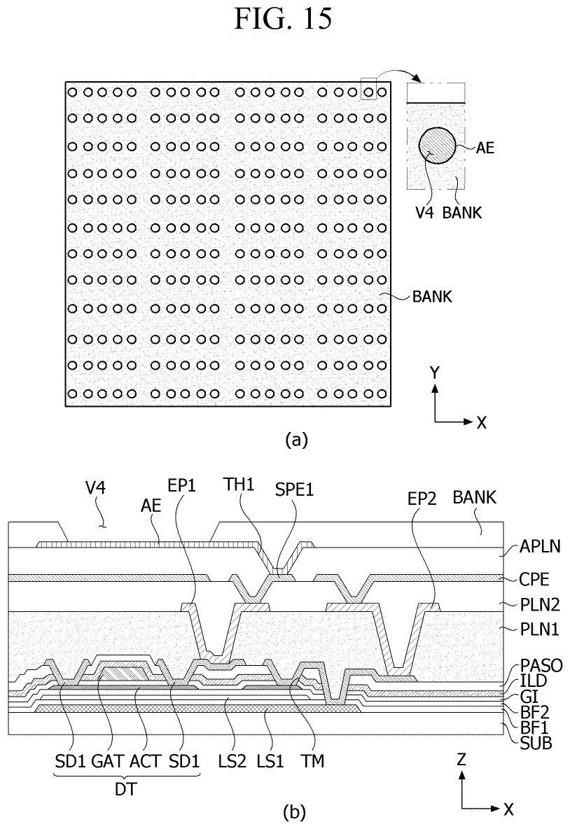

FIG. 15 shows (a) a plan view and (b) a cross-sectional view of an example display panel in which up to the bank is stacked, according to a first embodiment.

As shown in (b) of FIG. 15, the bank BANK may be disposed on the anode electrode AE and the third planarization layer APLN. The third planarization layer APLN is located below the bank BANK, which may improve the flatness of the display panel.

And the bank BANK may cover a portion of the anode electrode AE. In addition, the bank BANK may include a fourth via V4 opened in an area corresponding to the light-emitting area of the sub-pixel. A portion of the anode electrode AE may be exposed by the fourth via V4.

And the fourth via V4 may be spaced apart from the first through-hole TH1. This may improve flatness.

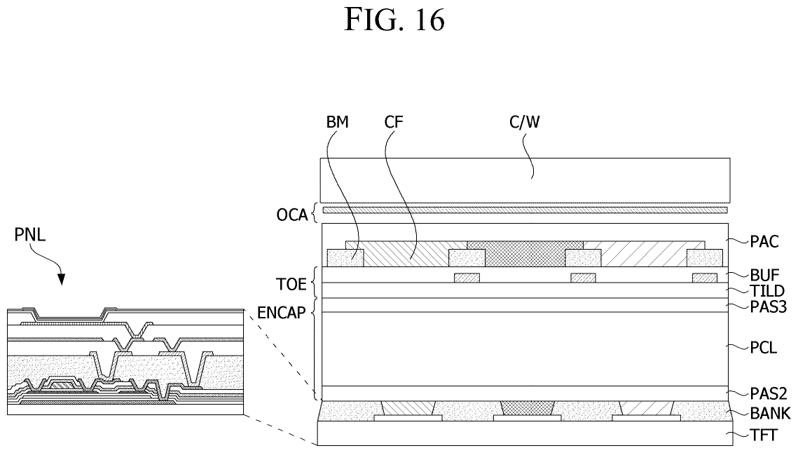

FIG. 16 is a cross-sectional view of the display panel according to an example embodiment.

As shown in FIG. 16, the display panel according to an embodiment may further include a lower panel (including the TFT, the bank BANK, the planarization layer PLN, etc.), and an encapsulation layer ENCAP, a touch structure TOE, and a color filter layer BM/CF that are sequentially disposed on the lower panel.

The encapsulation layer ENCAP may have a single-layer structure or a multi-layer structure. For example, the encapsulation layer ENCAP may include a third passivation layer PAS2, a first encapsulation layer PCL, and a second encapsulation layer PAS3.

For example, the third passivation layer PAS2 and the second encapsulation layer PAS3 may be inorganic films, and the first encapsulation layer PCL may be an organic film. Among the third passivation layer PAS2, the first encapsulation layer PCL, and the second encapsulation layer PAS3, the first encapsulation layer PCL may be the thickest and may serve as a planarization layer.

The first encapsulation layer PCL may be formed to have a smaller area than the third passivation layer PAS2. In this case, the first encapsulation layer PCL may be formed to expose opposite ends of the third passivation layer PAS2. And the first encapsulation layer PCL may acts as a buffer to relieve the stress between the layers occurred when the display panel 100 bends, and may also act to enhance the planarization performance. For example, the first encapsulation layer PCL may be formed of an organic insulating material, such as an acrylic resin, epoxy resin, polyimide, polyethylene, or silicon oxycarbide (SiOC). For example, the first encapsulation layer PCL may be formed by means of an inkjet method.

The second encapsulation layer PAS3 may minimize or block external moisture or oxygen from penetrating into the third passivation layer PAS2 of the inorganic material and the first encapsulation layer PCL of the organic material. For example, the second encapsulation layer PAS3 is formed of an inorganic insulating material such as silicon nitride (SiNx), silicon oxide (SiOx), silicon oxynitride (SiON), or aluminum oxide (Al₂O₃).

And when the touch sensor is of the type that is embedded in the display panel, the touch sensor may be disposed on the encapsulation layer ENCAP. And a touch buffer film may be disposed on the encapsulation layer ENCAP. The touch sensor may be disposed on the touch buffer film BUF. The touch sensor may include touch sensor metals and bridge metals located in different layers. A touch interlayer dielectric film TILD may be disposed between the touch sensor metals and the bridge metals. Cover window C/W and optical layer OCA may be disposed on the touch structure TOE.

And when the touch sensor is formed in the display panel, there may be chemical solutions used in the process (such as developer or etching solution) or moisture from the outside. Since the touch sensor is disposed on the touch buffer layer, it is possible to prevent or reduce chemical solutions, moisture, or the like from penetrating into the light-emitting elements containing organic material during the manufacturing process of the touch sensor. Therefore, the touch buffer film may prevent or reduce damage to the light-emitting element that is vulnerable to chemical solutions or moisture.

In addition, the color filter layer BM/CF may be located on the encapsulation layer ENCAP. In particular, the color filter layer BM/CF may be located on the touch structure TOE.

A protective layer PAC may be disposed to cover the touch sensor. The protective layer PAC may protect the touch sensor. The protective layer PAC may include an organic insulating material. Further, the protective layer PAC may have at least one unevenness to improve permeability.

According to an embodiment, since the third planarization layer APLN is further disposed in the display panel PNL, the lower film flatness may be further improved compared to the case where only the first planarization layer PLN1 and the second planarization layer PLN2 are disposed on the driving element DT. This improvement in flatness may also affect the encapsulation layer ENCAP, the color filter layer BM/CF, and the touch structure TOE above the display panel PNL. For example, the viewing angle may be further improved in the color filter layer BM/CF.

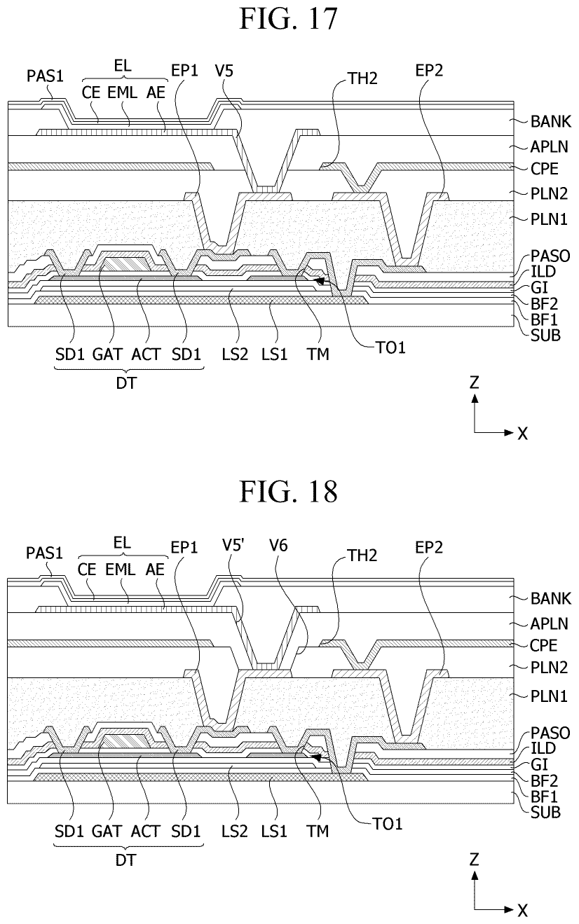

FIG. 17 is a cross-sectional view of an example display panel according to a second embodiment. FIG. 18 is a modified example of FIG. 17.

As shown in FIG. 17, in the display panel according to a second embodiment, the display panel includes a substrate SUB, a first light shielding layer LS1, a first buffer layer BF1, a second light shielding layer LS2, a second buffer layer BF2, a driving element DT, a storage capacitor (not shown), a gate insulating film GI, an interlayer dielectric film ILD, a first passivation layer PASO, a first planarization layer PLN1, an electrode pattern EP1, a driving voltage wire EP2, a second planarization layer PLN2, a compensation electrode layer CPE, a third planarization layer APLN, a light-emitting element EL, a bank or bank layer BANK, and a second passivation layer PAS1. Except for the description described below, the above descriptions of the present specification may be equally applied to the second embodiment.

The compensation electrode layer CPE may be disposed on the second planarization layer PLN2. In this case, the connecting electrode portion formed with the compensation electrode layer CPE may be omitted. In this embodiment, the compensation electrode layer CPE may include a second through-hole TH2, which is an aperture region. The second through-hole TH2 may at least partially overlap the electrode pattern EP1 in the stacking direction.

Further, the third planarization layer APLN and the second planarization layer PLN2 may include a fifth via V5. The fifth via V5 may penetrate the third planarization layer APLN and the second planarization layer PLN2.

And the anode electrode AE of the light-emitting element EL may be at least partially located within the fifth via V5. That is, the anode electrode AE of the light-emitting element EL may penetrate the second through-hole TH2. Alternatively, the anode electrode AE of the light-emitting element EL may be located on the inner side of the second through-hole TH2. Furthermore, the anode electrode AE may penetrate the third planarization layer APLN and the second planarization layer PLN2. Such a configuration may allow the anode electrode AE to be connected directly to the electrode pattern EP1. Accordingly, an electrical connection between the anode electrode AE and the electrode pattern EP1 may be made without a jumping electrode between the anode electrode AE and the electrode pattern EP1 between the second planarization layer PLN2 and the third planarization layer APLN.

As shown in FIG. 18, in a modified embodiment, the second planarization layer PLN2 may include a sixth via V6. The sixth via V6 may penetrate the second planarization layer PLN2. And the sixth via V6 may be located on the inner side of the second through-hole TH2. And the third planarization layer APLN may be disposed in the second through-hole TH2 and the sixth via V6. That is, the third planarization layer APLN and the second planarization layer PLN2 may partially overlap in a horizontal direction perpendicular to the stacking direction. In other words, the sixth via V6 may penetrate the second planarization layer PLN2 on the inner side of the second through-hole TH2. And a fifth via V5′ may penetrate only the third planarization layer APLN. Thus, the fifth via V5′ may be located on the inner side of the sixth via V6 and the second through-hole TH2. Furthermore, the fifth via V5′ may penetrate the third planarization layer APLN within the sixth via V6.

And the anode electrode AE may be disposed in the sixth via V6. Thus, the anode electrode AE may be spaced apart from the second planarization layer PLN2, even though it is disposed in the sixth via V6. In this way, the occurrence of cracks or the like that easily occur at the interface between the second planarization layer PLN2 and the third planarization layer APLN when penetrating both the stacked second and third planarization layers PLN2 and APLN may be suppressed. This may improve the structural reliability of the display panel.

In another modified example, the connecting electrode portion and the compensation electrode layer may be directly connected to the source-drain electrode pattern and the metal pattern, respectively, instead of to the electrode pattern and the driving voltage wire. That is, the connecting electrode portion and the compensation electrode layer may be electrically connected to the electrode pattern and the driving voltage wire through the source-drain electrode pattern and the metal pattern, respectively. Thus, the connecting electrode portion and the compensation electrode layer may penetrate the first planarization layer PLN1 and the second planarization layer PLN2.

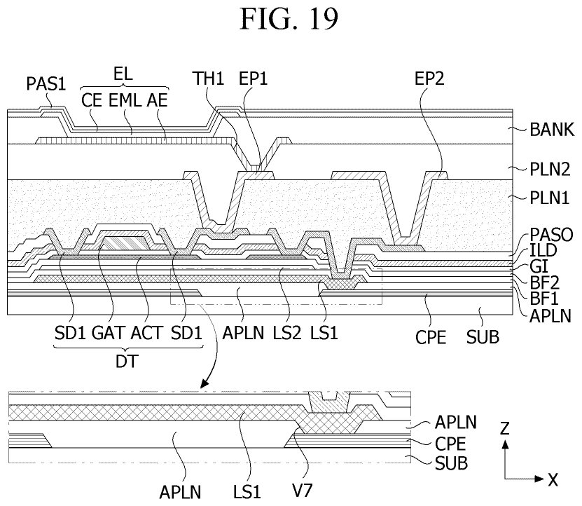

FIG. 19 is a cross-sectional view of an example display panel according to a third embodiment.

As shown in FIG. 19, the display panel according to a third embodiment includes a substrate SUB, a first light shielding layer LS1, a first buffer layer BF1, a second light shielding layer LS2, a second buffer layer BF2, a driving element DT, a storage capacitor (not shown), a gate insulating film GI, an interlayer dielectric film ILD, a first passivation layer PASO, a metal pattern TM, a first planarization layer PLN1, an electrode pattern EP1, a driving voltage wire EP2, a second planarization layer PLN2, a compensation electrode layer CPE, a third planarization layer APLN, a light-emitting element EL, a bank or bank layer BANK, and a second passivation layer PAS1. Except for the description described below, the above descriptions of the present specification may be equally applied to the third embodiment.

In this embodiment, the electrode pattern EP1 may be in direct contact with the anode electrode AE penetrating the second planarization layer PLN2.

The compensation electrode layer CPE may be disposed between the substrate SUB and the first light shielding layer LS1. The third planarization layer APLN may be located on the compensation electrode layer CPE. The third planarization layer APLN may be located between the compensation electrode layer CPE and the first light shielding layer LS1.

The third planarization layer APLN may cover the compensation electrode layer CPE. In case where the compensation electrode layer CPE is separated, the third planarization layer APLN may be inserted between the separated compensation electrode layer CPE and be in contact with the substrate SUB. However, embodiments of the present disclosure are not limited to those described above. The compensation electrode layer CPE may be integrally formed without being separated.

The first light shielding layer LS1 may be in contact with the metal pattern TM as well as the compensation electrode layer CPE. The first light shielding layer LS1 may penetrate the third planarization layer APLN and be electrically connected to the compensation electrode layer CPE. For example, a seventh via V7 may be formed in the third planarization layer APLN. A portion of the first light shielding layer LS1 may extend to the seventh via V7 and be electrically connected to the compensation electrode layer CPE. Thus, the compensation electrode layer CPE may be connected to the driving voltage wire EP2. This effectively lowers the resistance on the driving voltage wire EP2.

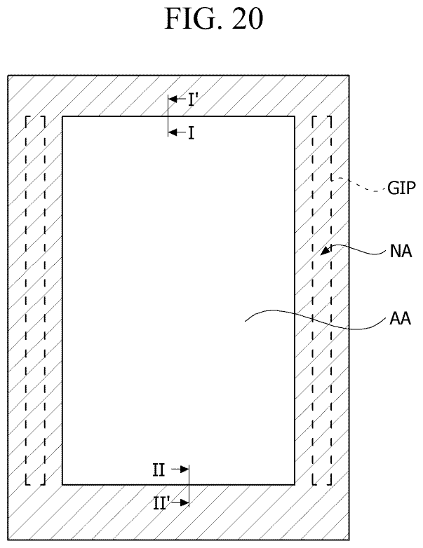

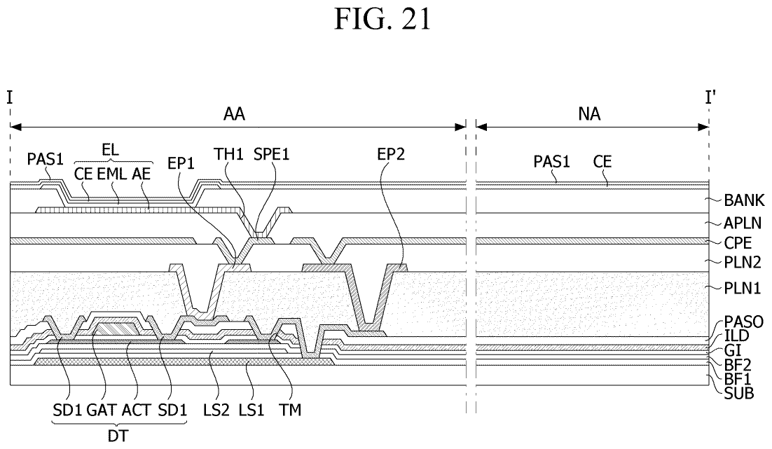

FIG. 20 is a plan view of a display device according to the embodiments of the present disclosure, and FIG. 21 is a cross-sectional view in the direction of line I-I′ in FIG. 20.

As shown in FIG. 20, in the display device according to the embodiments, the display panel may include a display area AA in which an image is displayed and a non-display area NA in which an image is not displayed.

In the display area AA, a plurality of sub-pixels may be disposed, and various signal lines for driving the plurality of sub-pixels may be disposed.

The non-display area NA may be an area outside the display area AA. The non-display area NA may be located adjacent to the display area AA. In the non-display area NA, various signal lines may be disposed and various driving circuits may be connected. The non-display area NA may be bent so that is not visible from the front, or may be covered by a case. The non-display area NA is also known as the bezel or bezel area.

The display panel may include a substrate and a plurality of sub-pixels SP disposed on the substrate. In addition, the display panel may further include several different types of signal lines used to drive a plurality of sub-pixels SP.

For example, different types of signal lines may include multiple data lines carrying data signals, multiple gate lines carrying gate signals, and so on.

The multiple data lines and the multiple gate lines may intersect each other. Each of the multiple data lines may be disposed while extending in the first direction. Each of the multiple gate lines may be disposed while extending in the second direction.

Here, the first direction may be the column direction and the second direction may be the row direction. Or the first direction may be the row direction and the second direction may be the column direction.

In addition, the gate driving circuit (or the gate driver 120 in FIG. 1) may be connected to the display panel by means of a tape automated bonding (TAB) method, a chip-on-glass (COG) or chip-on-panel (COP) method, or a chip-on-film (COF) method. Alternatively, the gate driving circuit may be formed in the non-display area NA of the display panel as a GIP (GATE In Pane) type. The gate driving circuit may be disposed on or connected to the substrate of the display panel. That is, the gate driving circuit may be disposed in the non-display area NA of the substrate if it is of the GIP type. The gate driving circuit may be connected to the substrate if it is a chip-on-glass (COG) type or chip-on-film (COF) type.

As further shown in FIG. 21, the compensation electrode layer CPE may be disposed extending from the display area AA to the non-display area NA. The compensation electrode layer CPE may be disposed in both the display area AA and the non-display area NA of the display panel. The compensation electrode layer CPE may also be disposed in areas other than the GIP in the non-display area NA. For example, the compensation electrode layer CPE may be formed on the entire display panel except for the connecting electrode portion. Therefore, the compensation effect of the resistance on the driving voltage wire may be further improved.

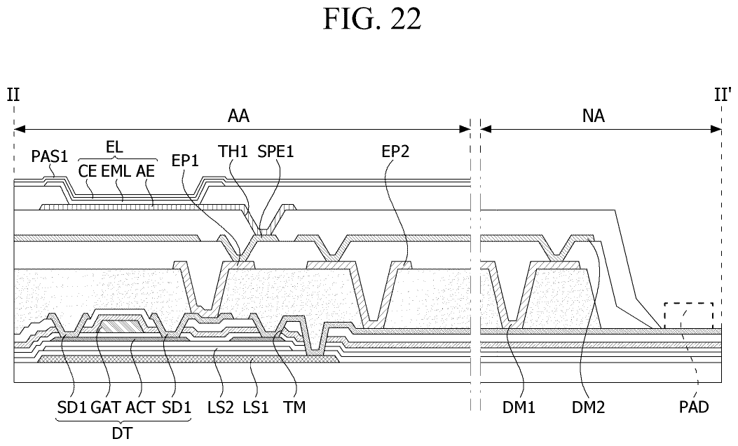

FIG. 22 is a cross-sectional view in the direction of line II-II′ in FIG. 20.

As shown in FIG. 22, the display panel may include pad electrodes PAD. The pad electrodes PAD may be formed on the non-display area NA adjacent to the end portion of the display panel. One pad electrode PAD may correspond to, but is not limited to, one sub-pixel.

The pad electrode PAD may be connected to a signal wire SL carrying a data signal and/or a gate signal. A first dummy electrode DM1 disposed on the same layer as the driving voltage wiring EP2 and a second dummy electrode DM2 disposed on the same layer as the compensation electrode layer CPE may be disposed in the non-display area NA. The first dummy electrode DM1 and the second dummy electrode DM2 may be electrically connected to the lower signal wire SL. In such a configuration, resistance is configured in parallel to reduce the resistance on the signal wire SL, thus allowing signals to be transmitted stably.

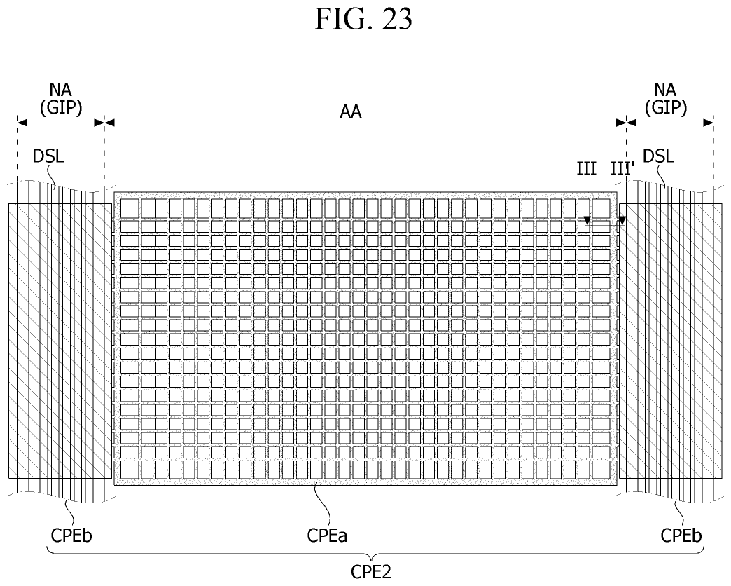

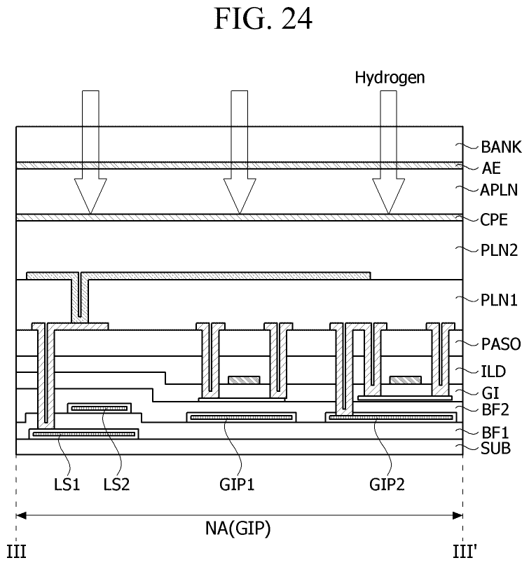

FIG. 23 is a diagram illustrating an example gate driver of the display panel. FIG. 24 is a cross-sectional view in the direction of line III-III′ in FIG. 23.

As shown in FIGS. 23 and 24, the gate driving circuit may be formed in the non-display area NA of the display panel. The gate driving circuit may be disposed on or connected to the substrate of the display panel. That is, a plurality of gate driving integrated circuits included in the gate driving circuit may be formed in the non-display area NA of the display panel (e.g., the bezel, etc.). In addition, a gate driving-related signal wire DSL for the gate driving circuit (hereinafter referred to as “GIP wire”) may also be disposed in the non-display area NA.

The GIP wire DSL may extend in one direction and may be disposed in plurality. The compensation electrode layer CPE may include a first part CPEa disposed in the display area AA and a second portion CPEb disposed in the non-display area NA. In particular, the second part CPEb may be located on the GIP, i.e., on the GIP wire DSL, in the non-displayed area NA. Thus, the second part CPEb may overlap the GIP wire DSL. Furthermore, the second part CPEb may be formed entirely in the non-displayed area NA. For example, the second part CPEb may be entirely disposed on the upper portion of the gate driving circuit. In such a configuration, the compensation electrode layer CPE may also be disposed on the gate driving circuit in the non-displayed area NA to further reduce the resistance on the driving voltage wire.

Furthermore, the compensation electrode layer CPE or the second part CPEb may be stacked in the stacking direction with the GIP elements GIP1 and GIP2 disposed in the non-display area NA. The compensation electrode layer CPE may cover the upper portion of the gate driving integrated circuit. With this configuration, in a process such as depositing the encapsulation layer on the display panel, the compensation electrode layer CPE may prevent or reduce particles (e.g., hydrogen) generated during its deposition from penetrating into the driving element, wire, and the like. This may improve the reliability of the display panel.

The descriptions of the problem to be solved, the means to solve the problem, and the effect described above does not specify the essential features of the claims, and therefore the scope of the claims is not limited by what is described in the specification.

Although the embodiments of the present disclosure have been described in more detail with reference to the accompanying drawings, the present disclosure is not necessarily limited to such embodiments, and may be variously modified within the scope thereof without departing from the technical spirit of the present disclosure. Therefore, the embodiments disclosed in the present disclosure are provided for illustrative purposes only and are not intended to limit the technical concept of the present disclosure, and the scope of the technical concept of the present disclosure is not limited thereto. Therefore, it should be understood that the embodiments described above are illustrative in all aspects and do not limit the present disclosure. The scope of protection of the present disclosure should be construed on the basis of the following claims and their equivalents, and all technical concepts within the equivalent scope thereof should be construed as falling within the scope of the present disclosure.

### DESCRIPTION OF REFERENCE NUMERALS

100: Display panel
110: Data driver
120: Gate driver
130: Timing controller
140: Power supply
R: Red sub-pixel
G: Green sub-pixel
B: Blue sub-pixel
Cst: Storage capacitor
Ca: Stabilization capacitor
EL: Light-emitting element

What is claimed is:

1. A display panel, comprising:
a substrate;
a driving element disposed on the substrate;
a first switch element disposed on the substrate;
a driving voltage wire electrically connected to the first switch element; and
a compensation electrode layer electrically connected to the driving voltage wire,
wherein the driving voltage wire and the compensation electrode layer are disposed in different layers.

2. The display panel of claim 1, further comprising:
a first planarization layer disposed on the driving element and the first switch element; and
a second planarization layer disposed on the driving voltage wire,
wherein the compensation electrode layer is disposed on the second planarization layer.

3. The display panel of claim 2, further comprising:
a third planarization layer disposed on the compensation electrode layer.

4. The display panel of claim 3, further comprising:
a metal pattern connected between the first switch element and the driving voltage wire; and
an electrode pattern configured to penetrate the first planarization layer and to be connect to a source-drain electrode pattern of the driving element,
wherein the driving voltage wire is configured to penetrate the first planarization layer and to be connected to the metal pattern.

5. The display panel of claim 4, wherein the compensation electrode layer is configured to penetrate the second planarization layer and to be electrically connected to the driving voltage wire.

6. The display panel of claim 4, further comprising:
an anode electrode connected to the electrode pattern;
an emission layer disposed on the anode electrode;
a cathode electrode disposed on the emissive layer; and
a connecting electrode portion disposed in the same layer as the compensation electrode layer and configured to connect the electrode pattern and the anode electrode.

7. The display panel of claim 6, wherein the connecting electrode portion is configured to penetrate the second planarization layer and to be electrically connected to the electrode pattern.

8. The display panel of claim 6, wherein the connecting electrode portion has the same material and thickness as those of the compensation electrode layer.

9. The display panel of claim 6, wherein the compensation electrode layer has a mesh shape and includes a plurality of aperture regions.

10. The display panel of claim 9, wherein the connecting electrode portion is disposed within each of the plurality of aperture regions on a plane.

11. The display panel of claim 1, wherein the compensation electrode layer is disposed to overlap the driving element and the first switch element.

12. The display panel of claim 6, wherein the third planarization layer includes a first through-hole overlapping the connecting electrode portion in a stacking direction.

13. The display panel of claim 1, wherein the compensation electrode layer is disposed below the driving element or the first switch element.

14. The display panel of claim 4, further comprising:
a first light shielding layer connected to the metal pattern between the substrate and the metal pattern; and
a second light shielding layer disposed between the first light shielding layer and a gate electrode of the driving element,
wherein the compensation electrode layer is disposed between the first light shielding layer and the substrate.

15. The display panel of claim 1, wherein:
the substrate includes a display area and a non-display area surrounding the display area, and
the compensation electrode layer extends to the non-display area.

16. The display panel of claim 15, wherein the compensation electrode layer extends onto a gate driver disposed in the non-display area.

17. A display device, comprising:
a display panel;
a data driver configured to drive the display panel; and
a gate driver configured to drive the display panel,
wherein the display panel includes:
a substrate;
a driving element disposed on the substrate;
a first switch element disposed on the substrate;
a driving voltage wire electrically connected to the first switch element; and
a compensation electrode layer electrically connected to the driving voltage wire, and
wherein the driving voltage wire and the compensation electrode layer are disposed in different layers.

18. The display device of claim 17, wherein the display panel further includes:
a first planarization layer disposed on the driving element and the first switch element; and
a second planarization layer disposed on the driving voltage wire, and
wherein the compensation electrode layer is disposed on the second planarization layer.

19. The display device of claim 18, wherein the display panel further includes:
a metal pattern connected between the first switch element and the driving voltage wire; and
an electrode pattern configured to penetrate the first planarization layer and to be connected to a source-drain electrode pattern of the driving element, and
wherein the driving voltage wire is configured to penetrate the first planarization layer and to be connected to the metal pattern.

20. The display device of claim 19, wherein the compensation electrode layer is configured to penetrate the second planarization layer and to be electrically connected to the driving voltage wire.
